(19) United States
(12) Patent Application Publication
(10) Pub. No.: US 2025/0254816 A1
(43) Pub. Date: Aug. 7, 2025

(54) SYSTEMS, APPARATUSES, METHODS, AND COMPUTER PROGRAM PRODUCTS FOR PROVIDING AN ASSET OPERATIONS HEAT OUTPUT TO AN ASSET

(71) Applicant: Honeywell International Inc., Charlotte, NC (US)

(72) Inventors: Gavin Towler, Inverness, IL (US); Eseoghene Jeroro, Chicago, IL (US); Gregory B. Kuzmanich, Arlington Heights, IL (US); Ankit Sethi, Clarence, NY (US); Sreevathsan Sivakumar, Salem (IN)

(21) Appl. No.: 18/827,237

(22) Filed: Sep. 6, 2024

Related U.S. Application Data
(60) Provisional application No. 63/549,301, filed on Feb. 2, 2024.

(51) Int. Cl. H05K 7/20

(52) U.S. Cl. CPC H05K 7/20009; H05K 7/20718

(57) ABSTRACT

Systems, apparatuses, methods, and computer program products are provided herein. For example, an embodiment described herein includes a heat pump and a heat pump operations apparatus. In some embodiments, the heat pump may be configured to receive a waste heat input from a data center. The waste heat input is associated with a first temperature. In some embodiments, the heat pump may be configured to receive a power input from a power source. In some embodiments, the heat pump may be configured to generate an asset operations heat output based at least in part on the waste heat input and the power input. The asset operations heat output is associated with a second temperature. The second temperature is greater than the first temperature. In some embodiments, the heat pump may be configured to providing the asset operations heat output to an asset.

### CROSS REFERENCE TO RELATED APPLICATIONS

This application claims the benefit of U.S. Provisional Application No. 63/549,301 filed Feb. 2, 2024, and entitled “Systems, Apparatuses, Methods, and Computer Program Products for Providing an Asset Operations Heat Output to an Asset,” which is hereby incorporated by reference in its entirety.

### TECHNOLOGICAL FIELD

Embodiments of the present disclosure relate generally to systems, apparatuses, methods, and computer program products for providing an asset operations heat output to an asset.

### BACKGROUND

Applicant has identified many technical challenges and difficulties associated with systems, apparatuses, methods, and computer program products for providing an asset operations heat output to an asset. Through applied effort, ingenuity, and innovation, Applicant has solved problems related to systems, apparatuses, methods, and computer program products for providing an asset operations heat output to an asset by developing solutions embodied in the present disclosure, which are described in detail below.

### BRIEF SUMMARY

Various embodiments described herein relate to systems, apparatuses, methods, and computer program products for providing an asset operations heat output to an asset.

In accordance with one aspect of the disclosure, a system is provided. In some embodiments, the system includes a heat pump. In some embodiments, the heat pump is configured to receive a waste heat input from a data center. In some embodiments, the waste heat input is associated with a first temperature. In some embodiments, the heat pump is configured to receive a power input from a power source. In some embodiments, the heat pump is configured to generate an asset operations heat output based at least in part on the waste heat input and the power input. In some embodiments, the asset operations heat output is associated with a second temperature. In some embodiments, the second temperature is greater than the first temperature. In some embodiments, the heat pump is configured to provide the asset operations heat output to an asset. In some embodiments, the system includes a heat pump operations apparatus. In some embodiments, the heat pump operations apparatus comprises at least one processor and at least one non-transitory memory including computer-coded instructions thereon. In some embodiments, the computer-coded instructions, with the at least one processor, cause the heat pump operations apparatus to generate heat pump data. In some embodiments, the computer-coded instructions, with the at least one processor, cause the heat pump operations apparatus to generate a heat pump impact interface component based on the heat pump impact data. In some embodiments, the heat pump impact interface component includes at least a portion of the heat pump impact data. In some embodiments, the computer-coded instructions, with the at least one processor, cause the heat pump operations apparatus to cause the heat pump impact interface component to be rendered to a heat pump impact interface associated with the heat pump operations apparatus.

In some embodiments, the computer-coded instructions, with the at least one processor, cause the heat pump operations apparatus to generate a heat pump impact determination interface component based on the heat pump impact data.

In some embodiments, the computer-coded instructions, with the at least one processor, cause the heat pump operations apparatus to cause the heat pump impact interface component to be rendered to the heat pump impact interface associated with the heat pump operations apparatus.

In some embodiments, the computer-coded instructions, with the at least one processor, cause the heat pump operations apparatus to perform, using a simulation tool, one or more lifecycle impact evaluations.

In some embodiments, the one or more lifecycle impact evaluations comprise one or more of a conventional decoupled lifecycle impact evaluation, a conventional integrated lifecycle impact evaluation, a solar decoupled lifecycle impact evaluation, a wind decoupled lifecycle impact evaluation, a solar integrated lifecycle impact evaluation, or a wind integrated lifecycle impact evaluation.

In some embodiments, the asset is a direct air capture system or a district heating system.

In some embodiments, the power source comprises solar power or wind power.

In some embodiments, the heat pump operations apparatus is a server heat pump operations apparatus.

In some embodiments, the heat pump is located at a first location and the server heat pump operations apparatus is located at a second location.

In some embodiments, the heat pump operations apparatus is a local heat pump operations apparatus.

In some embodiments, the heat pump is located at a first location and the local heat pump operations apparatus is located at the first location.

In some embodiments, the heat pump impact data is representative of at least greenhouse gas data.

In accordance with another aspect of the disclosure, a method is provided. In some embodiments, the method includes receiving a waste heat input from a data center.

In some embodiments, the waste heat input is associated with a first temperature

In some embodiments, the method includes receiving a power input from a power source.

In some embodiments, the method includes generating an asset operations heat output based on the waste heat input and the power input.

In some embodiments, the asset operations heat output is associated with a second temperature.

In some embodiments, the second temperature is greater than the first temperature.

In some embodiments, the method includes providing the asset operations heat output to an asset.

In some embodiments, the method includes generating heat pump impact data.

In some embodiments, the method includes generating a heat pump impact interface component based on the heat pump impact data.

In some embodiments, the heat pump impact interface component comprises at least a portion of the heat pump impact data.

In some embodiments, the method includes causing the heat pump impact interface component to be rendered to a heat pump impact interface associated with a heat pump operations apparatus.

In some embodiments, the method includes generating a heat pump impact determination interface component based on the heat pump impact data.

In some embodiments, the method includes causing the heat pump impact interface component to be rendered to the heat pump impact interface associated with the heat pump operations apparatus.

In some embodiments, the method includes performing, using a simulation tool, one or more lifecycle impact evaluations.

In some embodiments, the one or more lifecycle impact evaluations comprise one or more of a conventional decoupled lifecycle impact evaluation, a conventional integrated lifecycle impact evaluation, a solar decoupled lifecycle impact evaluation, a wind decoupled lifecycle impact evaluation, a solar integrated lifecycle impact evaluation, or a wind integrated lifecycle impact evaluation.

In some embodiments, the asset is a direct air capture system or a district heating system.

In some embodiments, the power source comprises solar power or wind power.

In some embodiments, the heat pump impact data is generated by a server heat pump operations apparatus.

In some embodiments, the heat pump impact data is representative of at least greenhouse gas data.

In accordance with another aspect of the disclosure, a non-transitory computer-readable medium is provided. In some embodiments, the non-transitory computer-readable medium stores software comprising instructions executable by one or more apparatuses. In some embodiments, the instructions, upon execution, cause the one or more apparatuses to receive a waste heat input from a data center. In some embodiments, the waste heat input is associated with a first temperature. In some embodiments, the instructions, upon such execution, cause the one or more apparatuses to receive a power input from a power source. In some embodiments, the instructions, upon such execution, cause the one or more apparatuses to generate an asset operations heat output based on the waste heat input and the power input. In some embodiments, the asset operations heat output is associated with a second temperature. In some embodiments, the second temperature is greater than the first temperature. In some embodiments, the instructions, upon such execution, cause the one or more apparatuses to provide the asset operations heat output to an asset. In some embodiments, the instructions, upon such execution, cause the one or more apparatuses to generate heat pump impact data. In some embodiments, the instructions, upon such execution, cause the one or more apparatuses to generate a heat pump impact interface component based on the heat pump impact data. In some embodiments, the heat pump impact interface component comprises at least a portion of the heat pump impact data. In some embodiments, the instructions, upon such execution, cause the one or more apparatuses to cause the heat pump impact interface component to be rendered to a heat pump impact interface associated with a heat pump operations apparatus.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates an exemplary block diagram of an environment in which embodiments of the present disclosure may operate;

FIG. 2 illustrates an exemplary block diagram of an example apparatus that may be specially configured in accordance with an example embodiment of the present disclosure;

FIG. 3 illustrates an example interface in accordance with one or more embodiments of the present disclosure;

FIG. 4 illustrates another example interface in accordance with one or more embodiments of the present disclosure;

FIG. 5 illustrates a flowchart of an example method in accordance with one or more embodiments of the present disclosure; and

FIGS. 6-17 illustrates example interfaces in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

The use of the term “circuitry” as used herein with respect to components of a system, or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communication circuitry, input/output circuitry, and the like. In some embodiments, other elements may provide or supplement the functionality of particular circuitry. Additionally, or alternatively, in some embodiments, other elements of a system and/or apparatus described herein may provide or supplement the functionality of another particular set of circuitry. For example, a processor may provide processing functionality to any of the sets of circuitry, a memory may provide storage functionality to any of the sets of circuitry, communications circuitry may provide network interface functionality to any of the sets of circuitry, and/or the like.

### Overview

Example embodiments disclosed herein address technical problems associated with systems, apparatuses, methods, and computer program products for providing an asset operations heat output to an asset. As would be understood by one skilled in the field to which this disclosure pertains, there are numerous example scenarios in which a user may use systems, apparatuses, methods, and computer program products for providing an asset operations heat output to an asset.

In many applications, it may be desirable to reduce lifecycle emissions in order to be carbon neutral or carbon negative. For example, it may be desirable to reduce the lifecycle emissions associated with a data center because data centers consume a large amount of power and, as a result, a data center has large lifecycle emissions. The lifecycle emissions of a data center may include, for example, the emissions associated with operating the data center as well as the construction of the data center, the construction of the materials that the data center is constructed from, the construction of the power source used to power the data center, the operation of the power source used to power the data center, and/or the like.

Example solutions for reducing the lifecycle emissions of a data center include operating the data center using renewable power sources (e.g., wind). However, since the lifecycle emissions of a data center include more than just the operation of the data center, it is not possible for a data center to be carbon neutral or carbon negative based only on operating the data center using renewable power sources. Additionally, although the amount of power provided by renewable power sources is rapidly increasingly, a data center may still have to at least partially rely on nonrenewable power sources (e.g., during peak load times). As such, there is a need for systems, apparatuses, methods, and computer program products that enable the reduction of the lifecycle emissions of a data center such that a data center can be carbon neutral or carbon negative.

Thus, to address these and/or other issues related to reducing the lifecycle emissions (e.g., of a data center), example systems, apparatuses, computer program products, and/or methods are disclosed herein. For example, an embodiment described herein includes a system. In some embodiments, the system may include a heat pump. In some embodiments, the heat pump may be configured to receive a waste heat input from a data center. In some embodiments, the waste heat input is associated with a first temperature. In some embodiments, the heat pump may be configured to receive a power input from a power source. In some embodiments, the heat pump may be configured to generate an asset operations heat output based at least in part on the waste heat input and the power input. In some embodiments, the asset operations heat output is associated with a second temperature. In some embodiments, the second temperature is greater than the first temperature. In some embodiments, the heat pump may be configured to providing the asset operations heat output to an asset. In some embodiments, the system may include a heat pump operations apparatus that is caused to generate heat pump impact data. Accordingly, the example systems, apparatuses, computer program products, and/or methods provided herein enable data center waste heat to be captured, applied to a heat pump to generate an asset operations heat output, and used by an asset (e.g., a direct air capture system). Thus, reducing the lifecycle emissions of a data center and enabling the data center to be carbon neutral or carbon negative.

### Example Systems and Apparatuses

Embodiments of the present disclosure herein include systems, apparatuses, methods, and computer program products configured for providing an asset operations heat output to an asset. It should be readily appreciated that the embodiments of the apparatus, systems, methods, and computer program product described herein may be configured in various additional and alternative manners in addition to those expressly described herein.

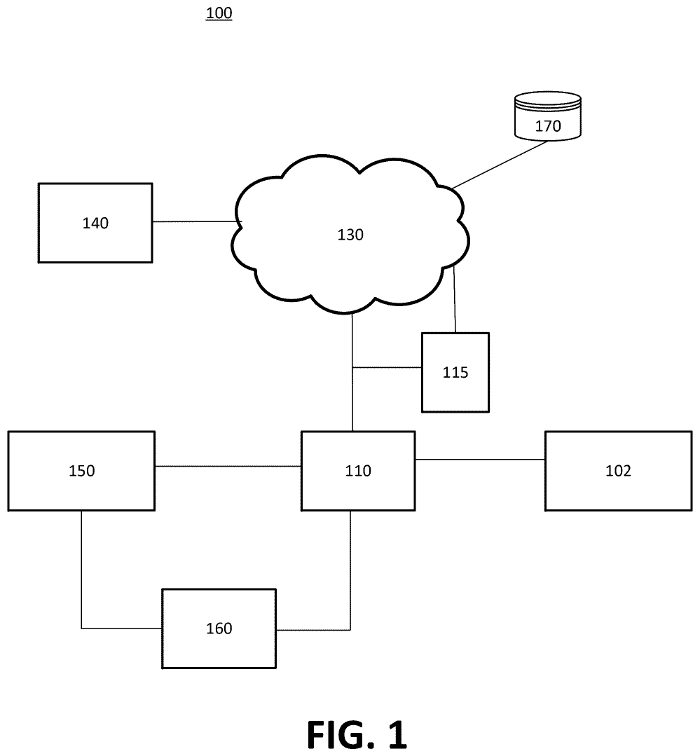

FIG. 1 illustrates an exemplary block diagram of an environment 100 in which embodiments of the present disclosure may operate. Specifically, FIG. 1 illustrates a data center 150. In some embodiments, the data center 150 may be configured to process, store, generate, and/or transport data. In some embodiments, the data center 150 may generate waste heat. For example, the data center 150 may generate waste heat while processing, storing, generating, and/or transporting data.

In some embodiments, the environment 100 may include a heat pump 110. In some embodiments, the heat pump 110 may be configured to transfer heat. In some embodiments, the heat pump 110 may be a portion of a system (e.g., the heat pump 110 may be one portion of a larger system). In some embodiments, the heat pump 110 may be communicatively coupled to the data center 150 to transmit data to the data center 150 and/or receive data from the data center 150. Additionally, or alternatively, the heat pump 110 may be physically coupled to the data center 150 to receive an input from the data center 150. In some embodiments, the heat pump 110 may be communicatively coupled to an asset 102 to transmit data to the asset 102 and/or receive data from the asset 102. Additionally, or alternatively, the heat pump 110 may be physically coupled to the data center 150 to receive an input from the data center 150. In some embodiments, the heat pump 110 may be located at a first location. In some embodiments, the asset 102 and/or the data center 150 may be located at the first location. In some embodiments, the first location may be a remote location. In some embodiments, the first location may include and/or be in proximity to a carbon capture and sequestration (CCS) plant that is configured to inject captured greenhouse gases (e.g., carbon dioxide) in the ground.

In some embodiments, the heat pump 110 may be associated with an evaporating temperature range of 10° C. to 40° C. In some embodiments, the heat pump 110 may be associated with a condensing temperature range of 70° C. to 105° C. In some embodiments, the heat pump 110 may be associated with a supply water temperature range of 65° C. to 100° C. In some embodiments, the heat pump 110 may be associated with a coefficient of performance (COP). For example, the heat pump 110 may be associated with a COP of approximately 2.2. In some embodiments, the heat pump 110 may include a Qpinch heat transformer. In some embodiments, the heat pump 110 may use one or more refrigerants. For example, the heat pump 110 may use one or more of R1234ze (E), R1234zc (Z), R1233zd (E), R1224yd (Z), R1336mzz (Z), and/or R1336mzz (E)

In some embodiments, the environment 100 may include a power source 160. In some embodiments, the power source 160 may be communicatively coupled to the data center 150 and/or the heat pump 110 to transmit data to the data center 150 and/or the heat pump 110 and/or receive data from the data center 150 and/or the heat pump 110. Additionally, or alternatively, the power source 160 may be physically coupled to the data center 150 and/or the heat pump 110 to provide power to the data center 150 and/or the heat pump 110. The power source 160 may be any type of source capable of generating and/or providing power. For example, the power source 160 may include solar power (e.g., a solar power plant). As another example, the power source 160 may include wind power (e.g., a wind power plant). As another example, the power source 160 may include natural gas (e.g., a natural gas plant). As another example, the power source 160 may include nuclear power (e.g., a nuclear power plant). As another example, the power source 160 may include hydroelectric power (e.g., a hydroelectric power plant). As another example, the power source 160 may include a mix of sources capable of generating and/or providing power (e.g., a mix of sources capable of generating and/or providing power from the electric grid).

In some embodiments, the environment 100 may include an asset 102. In some embodiments, the asset 102 may be a district heating system. In this regard, for example, the asset 102 may be configured to generate heat and distribute it to one or more buildings located in proximity of the asset 102. Additionally, or alternatively, in some embodiments, the asset 102 may be a low-medium grade heat application. Additionally, or alternatively, in some embodiments, the asset 102 may be direct air capture system (e.g., a direct air capture system associated with a geological sequestration system). In this regard, for example, the asset 102 may be configured to remove carbon dioxide and/or other greenhouse gases from the air. For example, the asset 102 may be configured to capture carbon dioxide from the air, compress the carbon dioxide, and/or at least in part cause the compressed carbon dioxide to be sent to geological storage. In this regard, for example, the asset 102 may include one or more components to remove carbon dioxide from the air. For example, the asset 102 may include an induced draft fan component, a carbon dioxide capture component having a liquid or solid sorbent, a regeneration component configured to desorb carbon dioxide from the sorbent, a compression component, a transportation component, and/or a sequestration component.

In some embodiments, the environment 100 may include a local heat pump operations apparatus 115. In some embodiments, for example, the local heat pump operations apparatus 115 may be configured to generate heat pump impact data. The local heat pump operations apparatus 115 may be electronically and/or communicatively coupled to the heat pump 110, a server heat pump operations apparatus 140, and/or one or more databases 170. The local heat pump operations apparatus 115 may be located remotely, in proximity of, and/or within the heat pump 110. In some embodiments, the local heat pump operations apparatus 115 is configured via hardware, software, firmware, and/or a combination thereof, to perform data intake of one or more types of data associated with the heat pump 110, the data center 150, and/or the asset 102. Additionally, or alternatively, in some embodiments, the local heat pump operations apparatus 115 is configured via hardware, software, firmware, and/or a combination thereof, to generate and/or transmit command(s) that control, adjust, or otherwise impact operations of one or more of the heat pump 110, the data center 150, and/or the asset 102. Additionally, or alternatively still, in some embodiments, the local heat pump operations apparatus 115 is configured via hardware, software, firmware, and/or a combination thereof, to perform data reporting and/or other data output process(es) associated with monitoring or otherwise analyzing operations of one or more of the asset 102 or specific component(s) thereof, for example for generating and/or outputting report(s) corresponding to the operations performed via the heat pump 110, the data center 150, and/or the asset 102. For example, in various embodiments, the local heat pump operations apparatus 115 may be configured to execute and/or perform one or more operations and/or functions described herein. In some embodiments, the local heat pump operations apparatus 115 may be located at the first location.

In some embodiments, the environment 100 may include a server heat pump operations apparatus 140. In some embodiments, for example, the server heat pump operations apparatus 140 may be configured to generate heat pump impact data. The server heat pump operations apparatus 140 may be electronically and/or communicatively coupled to the heat pump 110, a local heat pump operations apparatus 115, and/or one or more databases 170. The server heat pump operations apparatus 140 may be located remotely, in proximity of, and/or within the heat pump 110. In some embodiments, the server heat pump operations apparatus 140 is configured via hardware, software, firmware, and/or a combination thereof, to perform data intake of one or more types of data associated with the heat pump 110, the data center 150, and/or the asset 102. Additionally, or alternatively, in some embodiments, the server heat pump operations apparatus 140 is configured via hardware, software, firmware, and/or a combination thereof, to generate and/or transmit command(s) that control, adjust, or otherwise impact operations of one or more of the heat pump 110, the data center 150, and/or the asset 102. Additionally, or alternatively still, in some embodiments, the server heat pump operations apparatus 140 is configured via hardware, software, firmware, and/or a combination thereof, to perform data reporting and/or other data output process(es) associated with monitoring or otherwise analyzing operations of one or more of the asset 102 or specific component(s) thereof, for example for generating and/or outputting report(s) corresponding to the operations performed via the heat pump 110, the data center 150, and/or the asset 102. For example, in various embodiments, the server heat pump operations apparatus 140 may be configured to execute and/or perform one or more operations and/or functions described herein. In some embodiments, the server heat pump operations apparatus 140 may be located at a second location.

In some embodiments, the server heat pump operations apparatus 140 may form a heat pump operations apparatus. In some embodiments, the local heat pump operations apparatus 115 may form a heat pump operations apparatus. In some embodiments, the server heat pump operations apparatus 140 and the local heat pump operations apparatus 115 may form a heat pump operations apparatus. In some embodiments, the server heat pump operations apparatus 140 and/or the local heat pump operations apparatus 115 may be a portion of a system (e.g., the server heat pump operations apparatus 140 and/or the local heat pump operations apparatus 115 may be one portion of a larger system). For example, the server heat pump operations apparatus 140 and/or the local heat pump operations apparatus 115 may form part of a system with the heat pump 110 (e.g., the server heat pump operations apparatus 140 and/or the local heat pump operations apparatus 115 and the heat pump 110 together form a system).

The one or more databases 170 may be configured to receive, store, and/or transmit data. In some embodiments, the one or more databases 170 may be associated with heat pump impact data associated with the asset 102. In some embodiments, the heat pump impact data may be generated by a heat pump operations apparatus (e.g., the local heat pump operations apparatus 115 and/or the server heat pump operations apparatus 140). In some embodiments, the one or more databases 170 may be associated with heat pump impact data generated by a heat pump operations apparatus (e.g., the local heat pump operations apparatus 115 and/or the server heat pump operations apparatus 140) in real-time. Additionally, or alternatively, the one or more databases 170 may be associated with heat pump impact data generated by a heat pump operations apparatus (e.g., the local heat pump operations apparatus 115 and/or the server heat pump operations apparatus 140) on a periodic basis (e.g., the heat pump impact data may be generated by a heat pump operations apparatus (e.g., the local heat pump operations apparatus 115 and/or the server heat pump operations apparatus 140) once per day).

The network 130 may be embodied in any of a myriad of network configurations. In some embodiments, the network 130 may be a public network (e.g., the Internet). In some embodiments, the network 130 may be a private network (e.g., an internal localized, or closed-off network between particular devices). In some other embodiments, the network 130 may be a hybrid network (e.g., a network enabling internal communications between particular connected devices and external communications with other devices). In various embodiments, the network 130 may include one or more base station(s), relay(s), router(s), switch(es), cell tower(s), communications cable(s), routing station(s), and/or the like. In various embodiments, components of the environment 100 may be communicatively coupled to transmit data to and/or receive data from one another over the network 130. Such configuration(s) include, without limitation, a wired or wireless Personal Area Network (PAN), Local Area Network (LAN), Metropolitan Area Network (MAN), Wide Area Network (WAN), and/or the like.

Additionally, while FIG. 1 illustrates certain components as separate, standalone entities communicating over the network 130, various embodiments are not limited to this configuration. In other embodiments, one or more components may be directly connected and/or share hardware or the like.

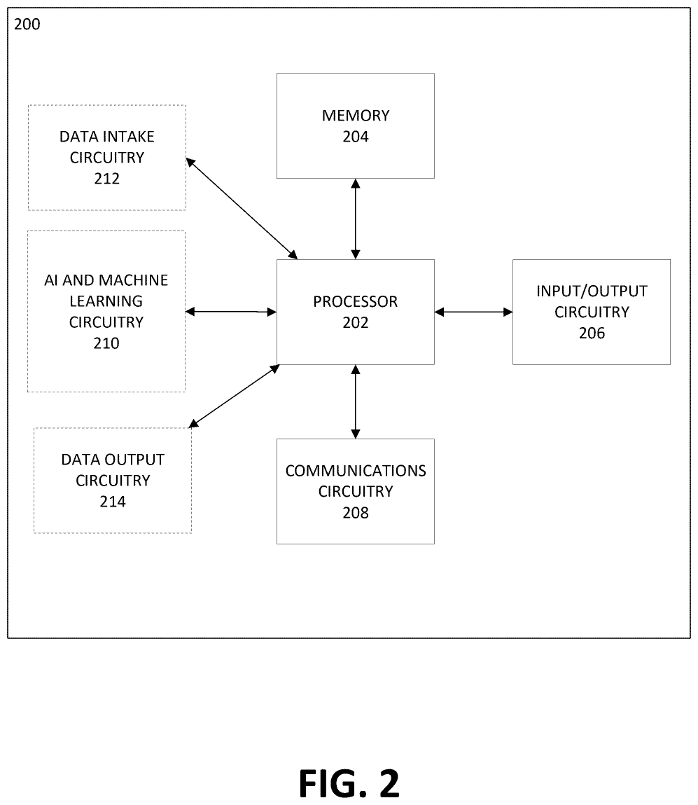

FIG. 2 illustrates an exemplary block diagram of an example apparatus that may be specially configured in accordance with an example embodiment of the present disclosure. Specifically, FIG. 2 depicts an example computing apparatus 200 (“apparatus 200”) specially configured in accordance with at least some example embodiments of the present disclosure. For example, the computing apparatus 200 may be embodied as one or more of a specifically configured personal computing apparatus, a specifically configured cloud-based computing apparatus, a specifically configured embedded computing device (e.g., configured for edge computing, and/or the like). Examples of an apparatus 200 may include but are not limited to the local heat pump operations apparatus 115, the server heat pump operations apparatus 140, and/or the one or more databases 170. The apparatus 200 includes processor 202, memory 204, input/output circuitry 206, communications circuitry 208, and/or optional artificial intelligence (“AI”) and machine learning circuitry 210. In some embodiments, the apparatus 200 is configured to execute and perform the operations described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), memory (ies), circuitry (ies), and/or the like to perform their associated functions such that duplicate hardware is not required for each set of circuitry.

In various embodiments, such as computing apparatus 200 of the local heat pump operations apparatus 115 and/or the server heat pump operations apparatus 140 may refer to, for example, one or more computers, computing entities, desktop computers, mobile phones, tablets, phablets, notebooks, laptops, distributed systems, servers, or the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein. In one embodiment, these functions, operations, and/or processes can be performed on data, content, information, and/or similar terms used herein. In this regard, the apparatus 200 embodies a particular, specially configured computing entity transformed to enable the specific operations described herein and provide the specific advantages associated therewith, as described herein.

Processor 202 or processor circuitry 202 may be embodied in a number of different ways. In various embodiments, the use of the terms “processor” should be understood to include a single core processor, a multi-core processor, multiple processors internal to the apparatus 200, and/or one or more remote or “cloud” processor(s) external to the apparatus 200. In some example embodiments, processor 202 may include one or more processing devices configured to perform independently. Alternatively, or additionally, processor 202 may include one or more processor(s) configured in tandem via a bus to enable independent execution of operations, instructions, pipelining, and/or multithreading.

In an example embodiment, the processor 202 may be configured to execute instructions stored in the memory 204 or otherwise accessible to the processor. Alternatively, or additionally, the processor 202 may be configured to execute hard-coded functionality. As such, whether configured by hardware or software methods, or by a combination thereof, processor 202 may represent an entity (e.g., physically embodied in circuitry) capable of performing operations according to embodiments of the present disclosure while configured accordingly. Alternatively, or additionally, processor 202 may be embodied as an executor of software instructions, and the instructions may specifically configure the processor 202 to perform the various algorithms embodied in one or more operations described herein when such instructions are executed. In some embodiments, the processor 202 includes hardware, software, firmware, and/or a combination thereof that performs one or more operations described herein.

In some embodiments, the processor 202 (and/or co-processor or any other processing circuitry assisting or otherwise associated with the processor) is/are in communication with the memory 204 via a bus for passing information among components of the apparatus 200.

Memory 204 or memory circuitry 204 may be non-transitory and may include, for example, one or more volatile and/or non-volatile memories. In some embodiments, the memory 204 includes or embodies an electronic storage device (e.g., a computer readable storage medium). In some embodiments, the memory 204 is configured to store information, data, content, applications, instructions, or the like, for enabling an apparatus 200 to carry out various operations and/or functions in accordance with example embodiments of the present disclosure.

Input/output circuitry 206 may be included in the apparatus 200. In some embodiments, input/output circuitry 206 may provide output to the user and/or receive input from a user. The input/output circuitry 206 may be in communication with the processor 202 to provide such functionality. The input/output circuitry 206 may comprise one or more user interface(s). In some embodiments, a user interface may include a display that comprises the interface(s) rendered as a web user interface, an application user interface, a user device, a backend system, or the like. In some embodiments, the input/output circuitry 206 also includes a keyboard, a mouse, a joystick, a touch screen, touch areas, soft keys a microphone, a speaker, or other input/output mechanisms. The processor 202 and/or input/output circuitry 206 comprising the processor may be configured to control one or more operations and/or functions of one or more user interface elements through computer program instructions (e.g., software and/or firmware) stored on a memory accessible to the processor (e.g., memory 204, and/or the like). In some embodiments, the input/output circuitry 206 includes or utilizes a user-facing application to provide input/output functionality to a computing device and/or other display associated with a user.

Communications circuitry 208 may be included in the apparatus 200. The communications circuitry 208 may include any means such as a device or circuitry embodied in either hardware or a combination of hardware and software that is configured to receive and/or transmit data from/to a network and/or any other device, circuitry, or module in communication with the apparatus 200. In some embodiments the communications circuitry 208 includes, for example, a network interface for enabling communications with a wired or wireless communications network. Additionally, or alternatively, the communications circuitry 208 may include one or more network interface card(s), antenna(s), bus(es), switch(es), router(s), modem(s), and supporting hardware, firmware, and/or software, or any other device suitable for enabling communications via one or more communications network(s). In some embodiments, the communications circuitry 208 may include circuitry for interacting with an antenna(s) and/or other hardware or software to cause transmission of signals via the antenna(s) and/or to handle receipt of signals received via the antenna(s). In some embodiments, the communications circuitry 208 enables transmission to and/or receipt of data from a user device, one or more sensors, and/or other external computing device(s) in communication with the apparatus 200.

Data intake circuitry 212 may be included in the apparatus 200. The data intake circuitry 212 may include hardware, software, firmware, and/or a combination thereof, designed and/or configured to capture, receive, request, and/or otherwise gather data associated with operations of the heat pump 110. In some embodiments, the data intake circuitry 212 includes hardware, software, firmware, and/or a combination thereof, that communicates with one or more sensor(s) component(s), and/or the like within the heat pump 110 to receive particular data associated with such operations of the heat pump 110. Additionally, or alternatively, in some embodiments, the data intake circuitry 212 includes hardware, software, firmware, and/or a combination thereof, that retrieves particular data associated with the heat pump 110 from one or more data repository/repositories accessible to the apparatus 200.

AI and machine learning circuitry 210 may be included in the apparatus 200. The AI and machine learning circuitry 210 may include hardware, software, firmware, and/or a combination thereof designed and/or configured to request, receive, process, generate, and transmit data, data structures, control signals, and electronic information for training and executing a trained AI and machine learning model configured for facilitating the operations and/or functionalities described herein. For example, in some embodiments the AI and machine learning circuitry 210 includes hardware, software, firmware, and/or a combination thereof, that identifies training data and/or utilizes such training data for training a particular machine learning model, AI, and/or other model to generate particular output data based at least in part on learnings from the training data. Additionally, or alternatively, in some embodiments, the AI and machine learning circuitry 210 includes hardware, software, firmware, and/or a combination thereof, that embodies or retrieves a trained machine learning model, AI and/or other specially configured model utilized to process inputted data. Additionally, or alternatively, in some embodiments, the AI and machine learning circuitry 210 includes hardware, software, firmware, and/or a combination thereof that processes received data utilizing one or more algorithm(s), function(s), subroutine(s), and/or the like, in one or more pre-processing and/or subsequent operations that need not utilize a machine learning or AI model.

Data output circuitry 214 may be included in the apparatus 200. The data output circuitry 214 may include hardware, software, firmware, and/or a combination thereof, that configures and/or generates an output based at least in part on data processed by the apparatus 200. In some embodiments, the data output circuitry 214 includes hardware, software, firmware, and/or a combination thereof, that generates a particular report based at least in part on the processed data, for example where the report is generated based at least in part on a particular reporting protocol. Additionally, or alternatively, in some embodiments, the data output circuitry 214 includes hardware, software, firmware, and/or a combination thereof, that configures a particular output data object, output data file, and/or user interface for storing, transmitting, and/or displaying. For example, in some embodiments, the data output circuitry 214 generates and/or specially configures a particular data output for transmission to another system sub-system for further processing. Additionally, or alternatively, in some embodiments, the data output circuitry 214 includes hardware, software, firmware, and/or a combination thereof, that causes rendering of a specially configured user interface based at least in part on data received by and/or processing by the apparatus 200.

In some embodiments, two or more of the sets of circuitries 202-214 are combinable. Alternatively, or additionally, one or more of the sets of circuitry 202-214 perform some or all of the operations and/or functionality described herein as being associated with another circuitry. In some embodiments, two or more of the sets of circuitry 202-214 are combined into a single module embodied in hardware, software, firmware, and/or a combination thereof. For example, in some embodiments, one or more of the sets of circuitry, for example the AI and machine learning circuitry 210, may be combined with the processor 202, such that the processor 202 performs one or more of the operations described herein with respect to the AI and machine learning circuitry 210.

With reference to FIGS. 1-17, in some embodiments, the heat pump 110 may be configured to receive a waste heat input. In some embodiments, the heat pump 110 may be configured to receive the waste heat input from the data center 150. In this regard, for example, the waste heat input may be representative of waste and/or excessive heat that is generated by the data center 150 when the data center 150 is processing, storing, generating, and/or transporting data. In some embodiments, the waste heat input may be associated with a first temperature. In some embodiments, the first temperature may be between 20° C. and 40° C. For example, the first temperature may be approximately 30° C.

In some embodiments, the heat pump 110 may be configured to receive a power input. In some embodiments, the power input may be received from the power source 160. In this regard, for example, power input may be based on solar power (e.g., the power source 160 is a solar plant). Additionally, or alternatively, the power input may be based on wind power (e.g., the power source 160 is a wind plant). Additionally, or alternatively, the power input may be based on natural gas (e.g., the power source 160 a natural gas plant). Additionally, or alternatively, the power input may be based on nuclear power (e.g., the power source 160 is a nuclear power plant). Additionally, or alternatively, the power input may be based on hydroelectric power (e.g., the power source 160 is a hydroelectric power plant). Additionally, or alternatively, the power input may be based on a mix of sources capable of generating and/or providing power (e.g., the power source 160 is an electric grid). In some embodiments, the power input may be between 40 megawatts (MW) and 60 MW. For example, the power input may be approximately 52 MW.

In some embodiments, the heat pump 110 may be configured to generate an asset operations heat output. In some embodiments, the asset operations heat output may be generated based at least in part on the waste heat input (e.g., the waste heat input received from the data center 150). Additionally, or alternatively, the asset operations heat output may be generated based at least in part on the power input (e.g., the power input received from the power source 160). In this regard, for example, the heat pump 110 may be configured to use heat from a source (e.g., the waste heat input) to heat up a refrigerant associated with the heat pump 110 (e.g., R1234ze (E)) to produce a saturated vapor. In some embodiments, the heat pump 110 may be configured to compress the saturated vapor to increase the temperature of the refrigerant to generate a heated refrigerant. In some embodiments, for example, the heat pump 110 may be configured to use the power input to compress the saturated vapor. In some embodiments, the heat pump 110 is configured to condense the heated refrigerant to produce an output that is a higher temperature than the input into the heat pump 110 (e.g., the asset operations heat output). In some embodiments, for example, the heat pump 110 may be configured to use the power input to condense the heated refrigerant.

In some embodiments, the asset operations heat output may be associated with a second temperature. In some embodiments, the second temperature may be between 85° C. and 105° C. For example, the second temperature may be approximately 95° C. In this regard, for example, the asset operations heat output may be associated with a second temperature that is less than 160° C. Additionally, or alternatively, for example, the asset operations heat output may be associated with a second temperature that is less than 140° C. In some embodiments, the second temperature may be greater than the first temperature. In this regard, for example, the heat pump 110 may be configured to intake waste heat and increase the temperature of the waste heat. In some embodiments, the second temperature may be of a sufficient temperature such that it may be used for the operation of the asset 102 (e.g., for the operation of a direct air capture system). That is, for example, by being between 85° C. and 105° C. the second temperature may be of a sufficient temperature such that it may be used for operation of the asset 102.

In some embodiments, the heat pump 110 may be configured to provide the asset operations heat output. In some embodiments, the heat pump 110 may be configured to provide the asset operations heat output to the asset 102. In this regard, for example, the heat pump 110 may be configured to provide the asset operations heat output to a distributed heating system. Additionally, or alternatively, the heat pump 110 may be configured to provide the asset operations heat output to a direct air capture system.

In some embodiments, a heat pump operations apparatus (e.g., the server heat pump operations apparatus 140 and/or the local heat pump operations apparatus 115) may be configured to generate heat pump impact data. In some embodiments, the heat pump operations apparatus (e.g., the server heat pump operations apparatus 140 and/or the local heat pump operations apparatus 115) may be configured to generate heat pump impact data based at least in part on the waste heat input, the power input, and/or the asset operations heat output.

In some embodiments, the heat pump impact data may include one or more items of data representative of an amount of power and/or energy associated with the waste heat input. In some embodiments, the heat pump impact data may include one or more items of data representative of an amount of power and/or energy associated with the asset operations heat output. For example, the heat pump impact data may include one or more items of data representative of approximately 100 MW of power associated with the asset operations heat output. In some embodiments, the heat pump impact data may include one or more items of data representative of a power draw of the data center 150. For example, the heat pump impact data may include one or more items of data representative of a power draw of the data center 150 of approximately 50 MW. In some embodiments, the heat pump impact data may include one or more items of data representative of a power draw of the heat pump 110. For example, the heat pump impact data may include one or more items of data representative of a power draw of the heat pump 110 of approximately 50 MW.

In some embodiments, the heat pump impact data may comprise greenhouse gas data. In some embodiments, the greenhouse gas data may comprise greenhouse gas capture data. In some embodiments, the greenhouse gas capture data may include one or more items of data representative of an amount of greenhouse gas (e.g., carbon dioxide) that is captured using the heat pump 110 and/or the asset 102 (e.g., how much greenhouse gas is removed from and/or prevented from entering the atmosphere by using the heat pump 110 and/or the asset 102).

In some embodiments, the greenhouse gas data may comprise greenhouse gas generation data. In this regard, for example, the greenhouse gas generation data may include one or more items of data indicative of an amount of greenhouse gas (e.g., carbon dioxide) that is embodied in the data center 150 (e.g., an amount of greenhouse gas that was generated in the construction of the data center 150 before the data center 150 went into operation). As another example, the greenhouse gas generation data may include one or more items of data indicative of an amount of greenhouse gas (e.g., carbon dioxide) that is associated with operating the data center 150 (e.g., operation of the data center 150 after it has been constructed). In some embodiments, the amount of greenhouse gas that is embodied in the data center 150 may be less than an amount of greenhouse gas that is associated with operating the data center.

As another example, the greenhouse gas generation data may include one or more items of data indicative of an amount of greenhouse gas (e.g., carbon dioxide) that is embodied in the heat pump 110 (e.g., an amount of greenhouse gas that was generated in the construction of the heat pump 110 before the heat pump 110 went into operation). As another example, the greenhouse gas generation data may include one or more items of data indicative of an amount of greenhouse gas (e.g., carbon dioxide) that is associated with operating the heat pump 110 (e.g., operation of the heat pump 110 after it has been constructed).

As another example, the greenhouse gas generation data may include one or more items of data indicative of an amount of greenhouse gas (e.g., carbon dioxide) that is embodied in the asset 102 (e.g., an amount of greenhouse gas that was generated in the construction of the asset 102 before the asset 102 went into operation). In this regard, for example, the greenhouse gas generation data may include one or more items of data indicative of an amount of greenhouse gas that is embodied in a direct air capture system (e.g., when the asset 102 is a direct air capture system). Additionally, or alternatively, for example, the greenhouse gas generation data may include one or more items of data indicative of an amount of greenhouse gas that is embodied in a district heating system (e.g., when the asset 102 is a district heating system). As another example, the greenhouse gas generation data may include one or more items of data indicative of an amount of greenhouse gas (e.g., carbon dioxide) that is associated with operating the asset 102 (e.g., operation of the asset 102 after it has been constructed). In this regard, for example, the greenhouse gas generation data may include one or more items of data indicative of an amount of greenhouse gas that is associated with operating a direct air capture system (e.g., when the asset 102 is a direct air capture system). In this regard, for example, the greenhouse gas generation data may include one or more items of data indicative of an amount of greenhouse gas that is associated with operating a district heating system (e.g., when the asset 102 is a district heating capture system).

As another example, the greenhouse gas generation data may include one or more items of data indicative of an amount of greenhouse gas (e.g., carbon dioxide) that is embodied in the power source 160 (e.g., an amount of greenhouse gas that was generated in the construction of power source 160 before the power source 160 went into operation). As another example, the greenhouse gas generation data may include one or more items of data indicative of an amount of greenhouse gas (e.g., carbon dioxide) that is associated with operating the power source 160 (e.g., operation of the power source 160 after it has been constructed). As another example, the greenhouse gas generation data may include one or more items of data indicative of an amount of greenhouse gas (e.g., carbon dioxide) that is associated with adsorbent associated with the asset 102 (e.g., when the asset 102 is a direct air capture system).

In some embodiments, the greenhouse gas data may include one or more items of data indicative of a total amount of greenhouse gas associated with the environment 100. For example, the greenhouse gas data may include one or more items of data indicative of an amount that is equal to the greenhouse gas capture data subtracted from the greenhouse gas generation data. In some embodiments, the greenhouse gas data may include one or more items of data that indicate that the total amount of greenhouse gas associated with the environment 100 is neutral or negative. Said differently, by using at least the heat pump 110 and/or the asset 102 (e.g., a direct air capture system), it may be possible for the data center 150 to be carbon neutral and/or carbon negative because the heat pump 110 and/or the asset 102 may enable the removal of more greenhouse gas from the atmosphere than is released into the atmosphere through the construction and/or operation of the data center 150. For example, by using at least the heat pump 110 and/or the asset 102 (e.g., a direct air capture system), it may be possible to offset between approximately 30% to 50% of the energy needed for the asset 102 (e.g., between approximately 30% to 50% of the energy needed for a direct air capture system).

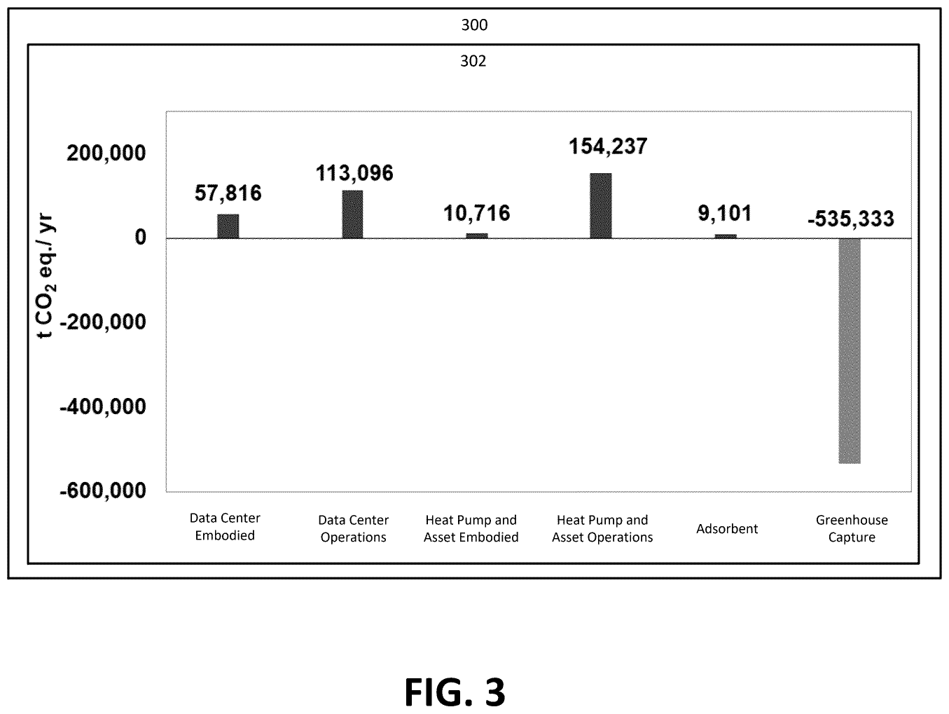

In some embodiments, the heat pump operations apparatus (e.g., the server heat pump operations apparatus 140 and/or the local heat pump operations apparatus 115) may be configured to generate a heat pump impact interface component 302. In some embodiments, the heat pump impact interface component 302 may comprise heat pump impact data. In some embodiments, such as illustrated in FIG. 3, the heat pump operations apparatus (e.g., the server heat pump operations apparatus 140 and/or the local heat pump operations apparatus 115) may be configured to cause rendering of the heat pump impact interface component 302 on a heat pump impact interface 300.

In some embodiments, for example, the heat pump impact interface component 302 may be configured to display heat pump impact data that is indicative of an amount of greenhouse gas (e.g., carbon dioxide) that is embodied in the data center 150. As another example, the heat pump impact interface component 302 may be configured to display heat pump impact data that is indicative of an amount of greenhouse gas (e.g., carbon dioxide) that is associated with operating the data center 150. As another example, the heat pump impact interface component 302 may be configured to display heat pump impact data that is indicative of an amount of greenhouse gas (e.g., carbon dioxide) that is embodied in the heat pump 110 and an amount of greenhouse gas (e.g., carbon dioxide) that is embodied in the asset 102.

As another example, the heat pump impact interface component 302 may be configured to display heat pump impact data that is indicative of an amount of greenhouse gas (e.g., carbon dioxide) that is associated with operating the heat pump 110 and an amount of greenhouse gas (e.g., carbon dioxide) that is associated with operating the asset 102. As another example, the heat pump impact interface component 302 may be configured to display heat pump impact data that is indicative of an amount of greenhouse gas (e.g., carbon dioxide) that is associated with adsorbent associated with the asset 102. As another example, the heat pump impact interface component 302 may be configured to display heat pump impact data that is indicative of amount of greenhouse gas (e.g., carbon dioxide) that is captured using at least the heat pump 110 and/or the asset 102.

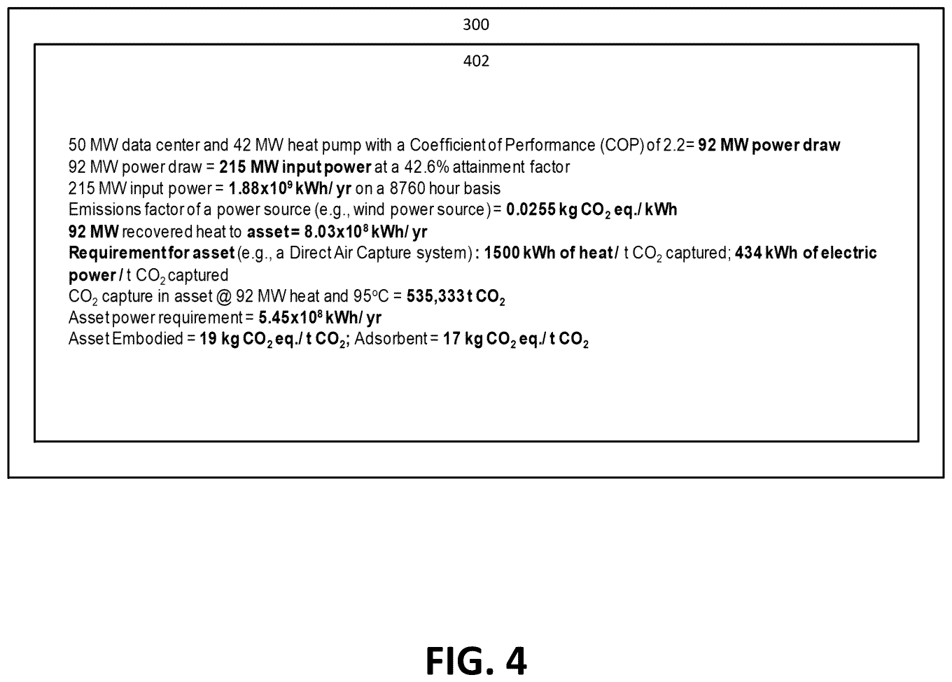

In some embodiments, the heat pump operations apparatus (e.g., the server heat pump operations apparatus 140 and/or the local heat pump operations apparatus 115) may be configured to generate a heat pump impact determination interface component 402. In some embodiments, the heat pump impact determination interface component 402 may comprise renderings of one or more determinations made by the heat pump operations apparatus when the heat pump operations apparatus is generating the heat pump impact data. In this regard, for example, the heat pump impact determination interface component 402 may be generated based on heat pump impact data. In some embodiments, such as illustrated in FIG. 4, the heat pump operations apparatus (e.g., the server heat pump operations apparatus 140 and/or the local heat pump operations apparatus 115) may be configured to cause rendering of the heat pump impact determination interface component 402 on the heat pump impact interface 300. In some embodiments, the heat pump impact interface 300 may be associated with the heat pump operations apparatus (e.g., the server heat pump operations apparatus 140 and/or the local heat pump operations apparatus 115). For example, the heat pump impact interface 300 may be an interface displayed by the heat pump operations apparatus (e.g., on the heat pump operations apparatus). As another example, the heat pump impact interface 300 may be displayed on an external computing device that has received heat pump impact data from the heat pump operations apparatus, the heat pump impact interface component 302 from the heat pump operations apparatus, and/or the heat pump impact determination interface component 402 from the heat pump operations apparatus.

In some embodiments, the heat pump operations apparatus (e.g., the server heat pump operations apparatus 140 and/or the local heat pump operations apparatus 115) may be configured to perform one or more lifecycle impact evaluations. In some embodiments, a lifecycle impact evaluation includes a lifecycle assessment (LCA). In this regard, for example, a lifecycle impact evaluation may include an evaluation of an environmental impact associated with a domain over a lifetime of one or more components of the domain. For example, a lifecycle impact evaluation may include an evaluation of an environmental impact associated with a domain that includes one or more power generation components and/or one or more heated components. In some embodiments, the heat pump operations apparatus (e.g., the server heat pump operations apparatus 140 and/or the local heat pump operations apparatus 115) may be configured to perform one or more lifecycle impact evaluations using a simulation tool (e.g., SimaPro 9.5.0), using a database (e.g., the cco-invent 3.8 database), and/or following a methodology (e.g., an ISO 14040/14044 methodology). In this regard, for example, the heat pump operations apparatus may be configured to establish global warming potential in metric tons equivalent of carbon dioxide per year (t CO₂ₑ/y) for various different power generation and/or heat generation techniques.

In some embodiments, the one or more lifecycle impact evaluations may include a conventional decoupled lifecycle impact evaluation. In this regard, for example, the heat pump operations apparatus (e.g., the server heat pump operations apparatus 140 and/or the local heat pump operations apparatus 115) may be configured to perform a conventional decoupled lifecycle impact evaluation. In some embodiments, a conventional decoupled lifecycle impact evaluation may be performed for a conventional decoupled domain that includes a data center component, an electric grid component configured to provide power to the data center (e.g., 50 megawatts (MW)), a boiler component (e.g., a boiler with 80% efficiency and powered by natural gas), and/or one or more units (e.g., one or more units being one or more homes to be heated). In some embodiments, the heat pump operations apparatus may be configured to generate conventional decoupled lifecycle impact data by performing a conventional decoupled lifecycle impact evaluation. In this regard, for example, the heat pump operations apparatus may be configured to generate conventional decoupled lifecycle impact data by performing one or more conventional decoupled lifecycle impact evaluations using a simulation tool (e.g., SimaPro 9.5.0), using a database (e.g., the cco-invent 3.8 database), and/or following an ISO 14040/14044 methodology.

In some embodiments, conventional decoupled lifecycle impact data may include one or more items of data representative and/or indicative of an amount of greenhouse gas (e.g., carbon dioxide) that is embodied in a data center component in the conventional decoupled domain (e.g., an amount of greenhouse gas that was generated in the construction of the data center component in the conventional decoupled domain before the data center component went into operation). Additionally, or alternatively, conventional decoupled lifecycle impact data may include one or more items of data representative and/or indicative of an amount of greenhouse gas (e.g., carbon dioxide) that is associated with operating the data center component in the conventional decoupled domain (e.g., operation of the data center component in the conventional decoupled domain after it has been constructed). Additionally, or alternatively, conventional decoupled lifecycle impact data may include one or more items of data representative and/or indicative of a number of units associated with the conventional decoupled domain. For example, conventional decoupled lifecycle impact data may include one or more items of data representative and/or indicative of a number of homes that may be heated by the boiler component of the conventional decoupled domain.

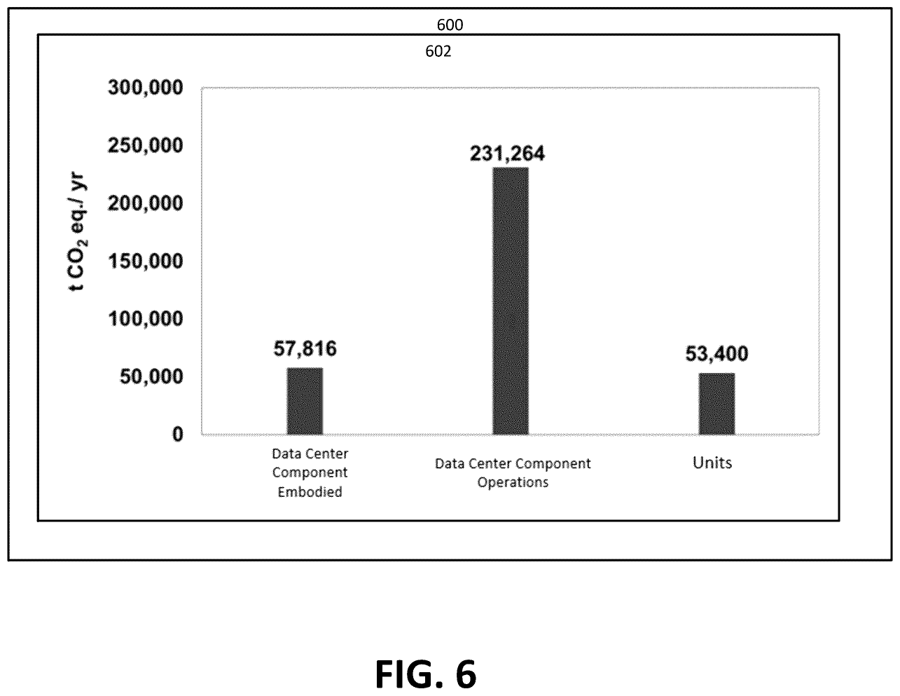

In some embodiments, the heat pump operations apparatus (e.g., the server heat pump operations apparatus 140 and/or the local heat pump operations apparatus 115) may be configured to generate a conventional decoupled lifecycle impact interface component 602. In some embodiments, the conventional decoupled lifecycle impact interface component 602 may comprise conventional decoupled lifecycle impact data. In some embodiments, such as illustrated in FIG. 6, the heat pump operations apparatus (e.g., the server heat pump operations apparatus 140 and/or the local heat pump operations apparatus 115) may be configured to cause rendering of the conventional decoupled lifecycle impact interface component 602 on a lifecycle impact interface 600.

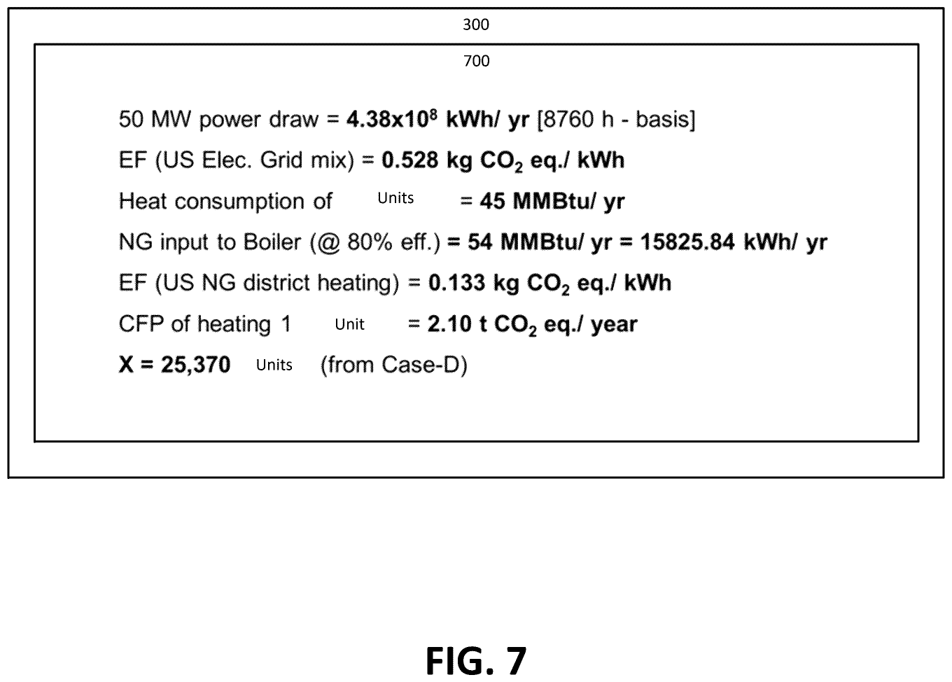

In some embodiments, the heat pump operations apparatus (e.g., the server heat pump operations apparatus 140 and/or the local heat pump operations apparatus 115) may be configured to generate a conventional decoupled lifecycle impact determination interface component 700. In some embodiments, the conventional decoupled lifecycle impact determination interface component 700 may comprise renderings of one or more determinations made by the heat pump operations apparatus when the heat pump operations apparatus is generating the conventional decoupled lifecycle impact data. In some embodiments, such as illustrated in FIG. 7, the heat pump operations apparatus (e.g., the server heat pump operations apparatus 140 and/or the local heat pump operations apparatus 115) may be configured to cause rendering of the conventional decoupled lifecycle impact determination interface component 700 on the lifecycle impact interface 600.

In some embodiments, the one or more lifecycle impact evaluations may include a conventional integrated lifecycle impact evaluation. In this regard, for example, the heat pump operations apparatus (e.g., the server heat pump operations apparatus 140 and/or the local heat pump operations apparatus 115) may be configured to perform a conventional integrated lifecycle impact evaluation. In some embodiments, a conventional integrated lifecycle impact evaluation may be performed for a conventional integrated domain that includes a data center component, a gas turbine component configured to provide power to a data center and a district heating component, the district heating component configured to provide heating to a first set (Y) of units (e.g., a first set (Y) of units being a first set of homes to be heated), the first set (Y) of units, a boiler component (e.g., a boiler with 80% efficiency and powered by natural gas) configured to heat the first set (Y) of units and/or a second set (X) of units (e.g., the second set (X) of units being a second set of homes to be heated). In some embodiments, the heat pump operations apparatus may be configured to generate conventional integrated lifecycle impact data by performing a conventional integrated lifecycle impact evaluation. In this regard, for example, the heat pump operations apparatus may be configured to generate conventional integrated lifecycle impact data by performing one or more conventional integrated lifecycle impact evaluations using a simulation tool (e.g., SimaPro 9.5.0), using a database (e.g., the eco-invent 3.8 database), and/or following an ISO 14040/14044 methodology.

In some embodiments, conventional integrated lifecycle impact data may include one or more items of data representative and/or indicative of an amount of greenhouse gas (e.g., carbon dioxide) that is embodied in a data center component in the conventional integrated domain (e.g., an amount of greenhouse gas that was generated in the construction of the data center component in the conventional integrated domain before the data center component went into operation). Additionally, or alternatively, conventional integrated lifecycle impact data may include one or more items of data representative and/or indicative of an amount of greenhouse gas (e.g., carbon dioxide) that is associated with operating the data center component in the conventional integrated domain (e.g., operation of the data center component in the conventional integrated domain after it has been constructed). Additionally, or alternatively, conventional integrated lifecycle impact data may include one or more items of data representative and/or indicative of a number of units associated with the conventional integrated domain (e.g., the first set (Y) of units and the second set of units (X)). For example, conventional integrated lifecycle impact data may include one or more items of data representative and/or indicative of a number of homes that may be heated by the boiler component of the conventional integrated domain.

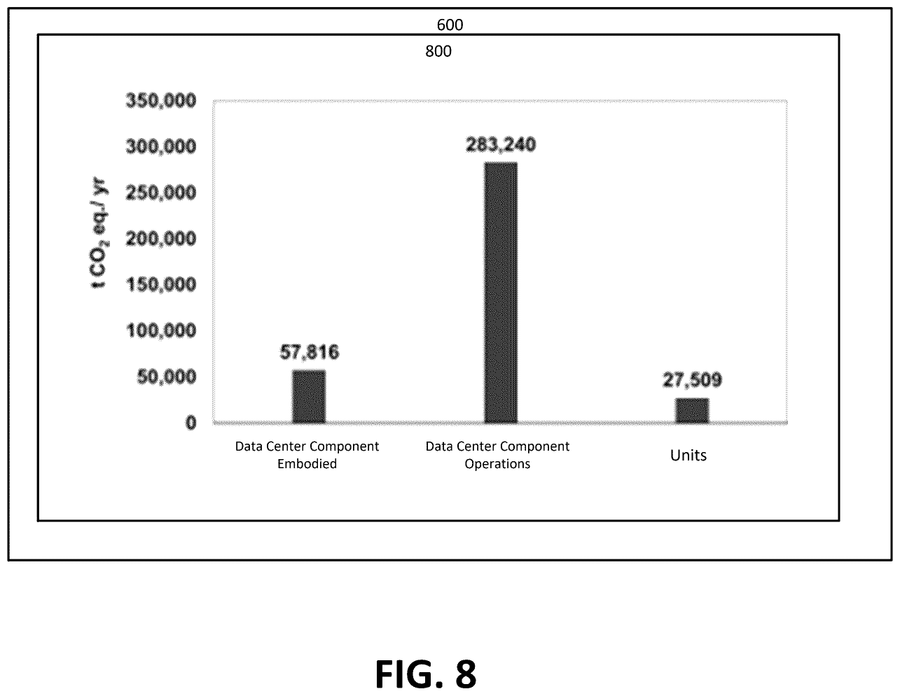

In some embodiments, the heat pump operations apparatus (e.g., the server heat pump operations apparatus 140 and/or the local heat pump operations apparatus 115) may be configured to generate a conventional integrated lifecycle impact interface component 800. In some embodiments, the conventional integrated lifecycle impact interface component 800 may comprise conventional integrated lifecycle impact data. In some embodiments, such as illustrated in FIG. 8, the heat pump operations apparatus (e.g., the server heat pump operations apparatus 140 and/or the local heat pump operations apparatus 115) may be configured to cause rendering of the conventional integrated lifecycle impact interface component 800 on a lifecycle impact interface 600.

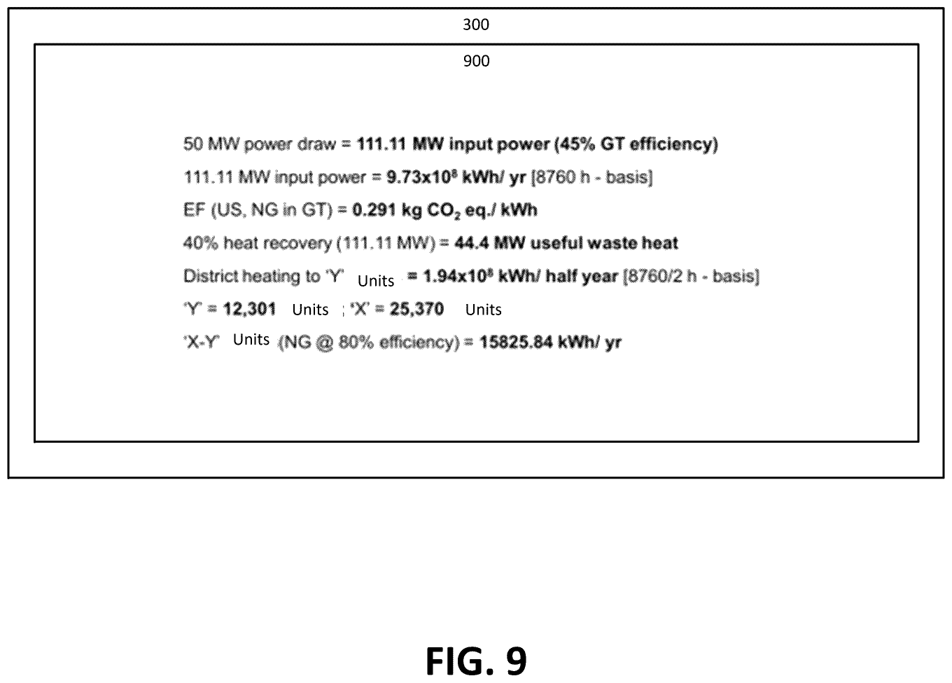

In some embodiments, the heat pump operations apparatus (e.g., the server heat pump operations apparatus 140 and/or the local heat pump operations apparatus 115) may be configured to generate a conventional integrated lifecycle impact determination interface component 900. In some embodiments, the conventional integrated lifecycle impact determination interface component 900 may comprise renderings of one or more determinations made by the heat pump operations apparatus when the heat pump operations apparatus is generating the conventional integrated lifecycle impact data. In some embodiments, such as illustrated in FIG. 9, the heat pump operations apparatus (e.g., the server heat pump operations apparatus 140 and/or the local heat pump operations apparatus 115) may be configured to cause rendering of the conventional integrated lifecycle impact determination interface component 900 on the lifecycle impact interface 600.

In some embodiments, the one or more lifecycle impact evaluations may include a solar decoupled lifecycle impact evaluation. In this regard, for example, the heat pump operations apparatus (e.g., the server heat pump operations apparatus 140 and/or the local heat pump operations apparatus 115) may be configured to perform a solar decoupled lifecycle impact evaluation. In some embodiments, a solar decoupled lifecycle impact evaluation may be performed for a solar decoupled domain that includes a data center component, a solar power component configured to provide power to the data center (e.g., 50 megawatts (MW)), boiler component (e.g., a boiler with 80% efficiency and powered by natural gas) configured to heat one or more units (X), and/or the one or more units (X) (e.g., the one or more units (X) being one or more homes to be heated). In some embodiments, the heat pump operations apparatus may be configured to generate solar decoupled lifecycle impact data by performing a solar decoupled lifecycle impact evaluation. In this regard, for example, the heat pump operations apparatus may be configured to generate solar decoupled lifecycle impact data by performing one or more solar decoupled lifecycle impact evaluations using a simulation tool (e.g., SimaPro 9.5.0), using a database (e.g., the eco-invent 3.8 database), and/or following an ISO 14040/14044 methodology.

In some embodiments, solar decoupled lifecycle impact data may include one or more items of data representative and/or indicative of an amount of greenhouse gas (e.g., carbon dioxide) that is embodied in a data center component in the solar decoupled domain (e.g., an amount of greenhouse gas that was generated in the construction of the data center component in the solar decoupled domain before the data center component went into operation). Additionally, or alternatively, solar decoupled lifecycle impact data may include one or more items of data representative and/or indicative of an amount of greenhouse gas (e.g., carbon dioxide) that is associated with operating the data center component in the solar decoupled domain (e.g., operation of the data center component in the solar decoupled domain after it has been constructed). Additionally, or alternatively, solar decoupled lifecycle impact data may include one or more items of data representative and/or indicative of a number of units associated with the solar decoupled domain (e.g., the one or more units (X)). For example, solar decoupled lifecycle impact data may include one or more items of data representative and/or indicative of a number of homes that may be heated by the boiler component of the solar decoupled domain.

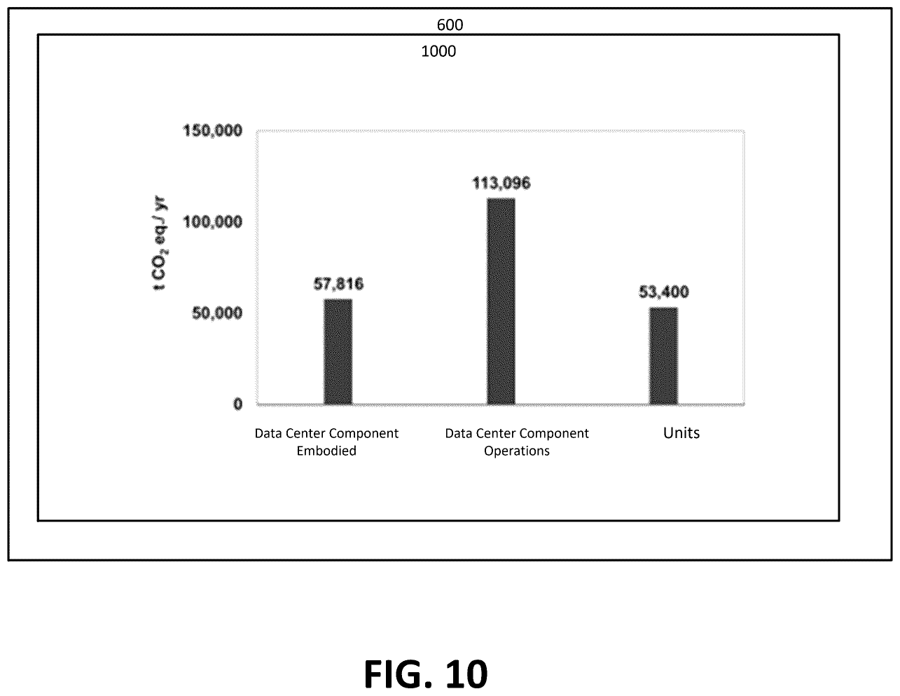

In some embodiments, the heat pump operations apparatus (e.g., the server heat pump operations apparatus 140 and/or the local heat pump operations apparatus 115) may be configured to generate a solar decoupled lifecycle impact interface component 1000. In some embodiments, the solar decoupled lifecycle impact interface component 1000 may comprise solar decoupled lifecycle impact data. In some embodiments, such as illustrated in FIG. 10, the heat pump operations apparatus (e.g., the server heat pump operations apparatus 140 and/or the local heat pump operations apparatus 115) may be configured to cause rendering of the solar decoupled lifecycle impact interface component 1000 on a lifecycle impact interface 600.

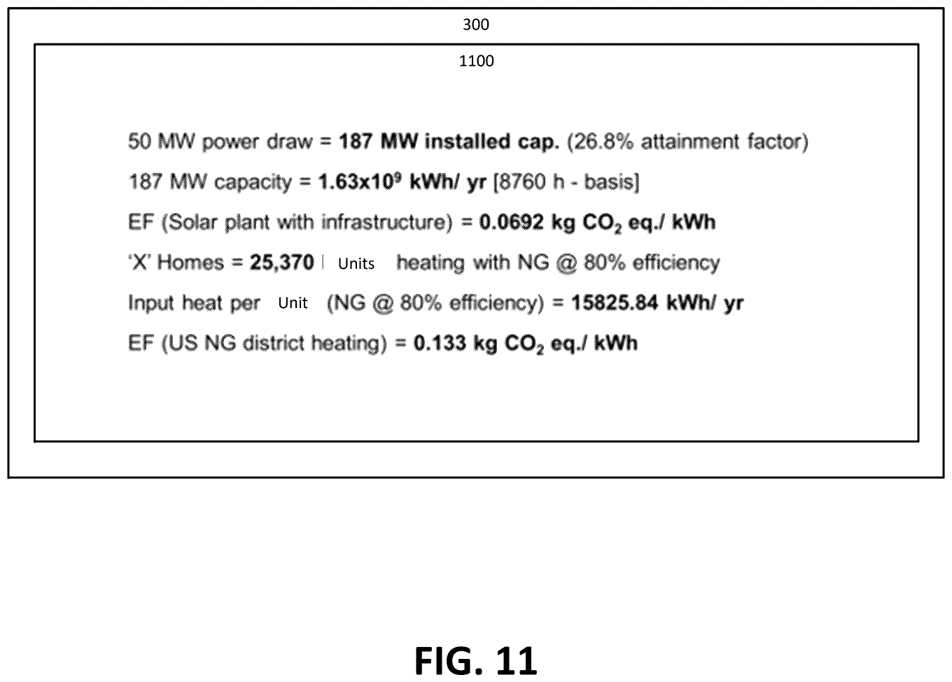

In some embodiments, the heat pump operations apparatus (e.g., the server heat pump operations apparatus 140 and/or the local heat pump operations apparatus 115) may be configured to generate a solar decoupled lifecycle impact determination interface component 1100. In some embodiments, the solar decoupled lifecycle impact determination interface component 1100 may comprise renderings of one or more determinations made by the heat pump operations apparatus when the heat pump operations apparatus is generating the solar decoupled lifecycle impact data. In some embodiments, such as illustrated in FIG. 11, the heat pump operations apparatus (e.g., the server heat pump operations apparatus 140 and/or the local heat pump operations apparatus 115) may be configured to cause rendering of the solar decoupled lifecycle impact determination interface component 1100 on the lifecycle impact interface 600.

In some embodiments, the one or more lifecycle impact evaluations may include a wind decoupled lifecycle impact evaluation. In this regard, for example, the heat pump operations apparatus (e.g., the server heat pump operations apparatus 140 and/or the local heat pump operations apparatus 115) may be configured to perform a wind decoupled lifecycle impact evaluation. In some embodiments, a wind decoupled lifecycle impact evaluation may be performed for a wind decoupled domain that includes a data center component, a wind power component configured to provide power to the data center (e.g., 50 megawatts (MW)), a boiler component (e.g., a boiler with 80% efficiency and powered by natural gas) configured to heat one or more units (X), and/or the one or more units (X) (e.g., the one or more units (X) being one or more homes to be heated). In some embodiments, the heat pump operations apparatus may be configured to generate wind decoupled lifecycle impact data by performing a wind decoupled lifecycle impact evaluation. In this regard, for example, the heat pump operations apparatus may be configured to generate wind decoupled lifecycle impact data by performing one or more wind decoupled lifecycle impact evaluations using a simulation tool (e.g., SimaPro 9.5.0), using a database (e.g., the eco-invent 3.8 database), and/or following an ISO 14040/14044 methodology.

In some embodiments, wind decoupled lifecycle impact data may include one or more items of data representative and/or indicative of an amount of greenhouse gas (e.g., carbon dioxide) that is embodied in a data center component in the wind decoupled domain (e.g., an amount of greenhouse gas that was generated in the construction of the data center component in the wind decoupled domain before the data center component went into operation). Additionally, or alternatively, wind decoupled lifecycle impact data may include one or more items of data representative and/or indicative of an amount of greenhouse gas (e.g., carbon dioxide) that is associated with operating the data center component in the wind decoupled domain (e.g., operation of the data center component in the wind decoupled domain after it has been constructed). Additionally, or alternatively, wind decoupled lifecycle impact data may include one or more items of data representative and/or indicative of a number of units associated with the wind decoupled domain (e.g., the one or more units (X)). For example, wind decoupled lifecycle impact data may include one or more items of data representative and/or indicative of a number of homes that may be heated by the boiler component of the wind decoupled domain.

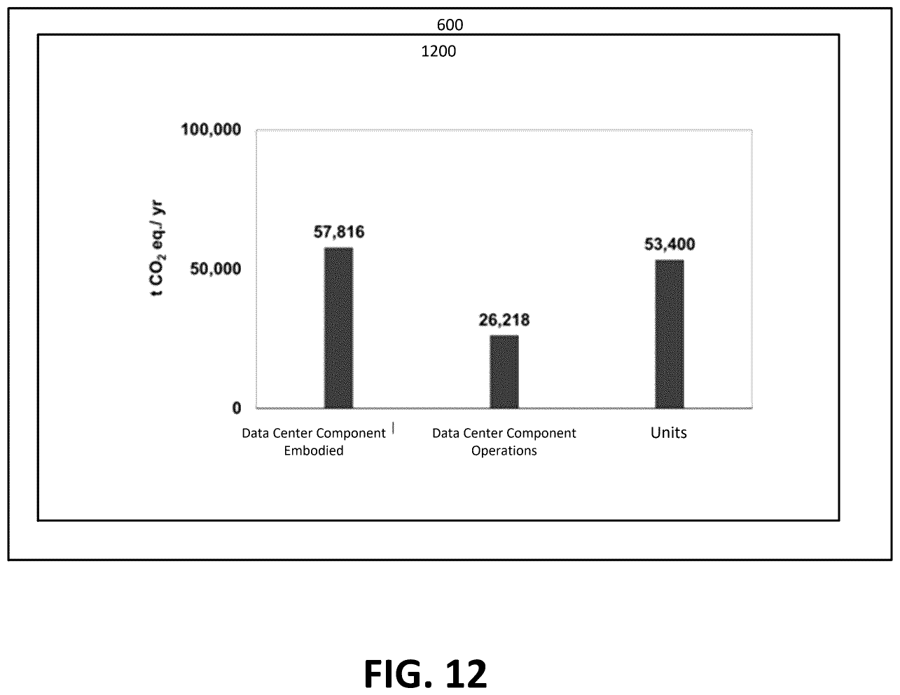

In some embodiments, the heat pump operations apparatus (e.g., the server heat pump operations apparatus 140 and/or the local heat pump operations apparatus 115) may be configured to generate a wind decoupled lifecycle impact interface component 1200. In some embodiments, the wind decoupled lifecycle impact interface component 1200 may comprise wind decoupled lifecycle impact data. In some embodiments, such as illustrated in FIG. 12, the heat pump operations apparatus (e.g., the server heat pump operations apparatus 140 and/or the local heat pump operations apparatus 115) may be configured to cause rendering of the wind decoupled lifecycle impact interface component 1200 on a lifecycle impact interface 600.

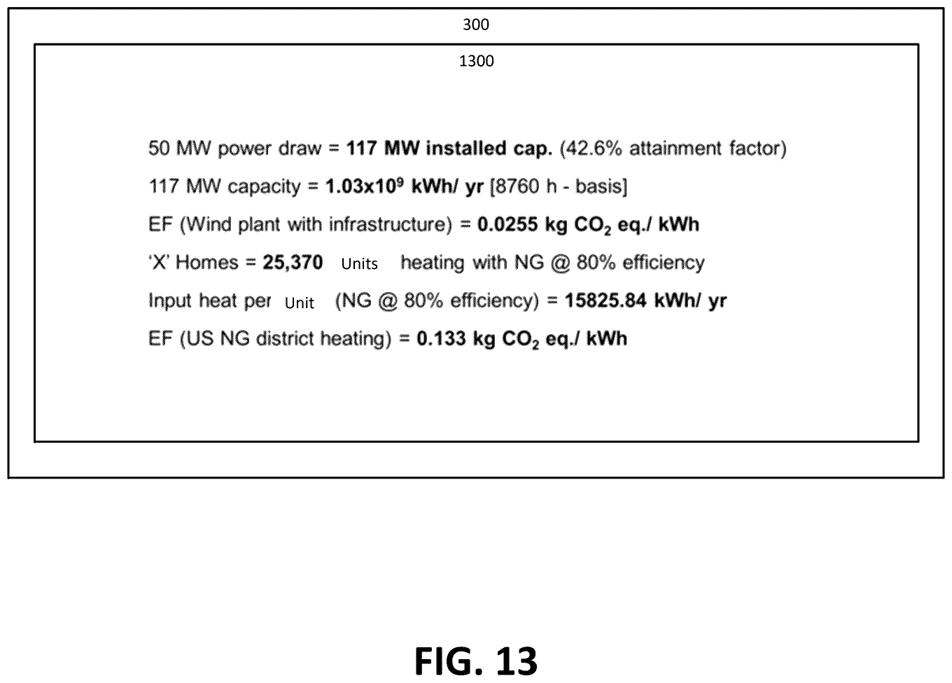

In some embodiments, the heat pump operations apparatus (e.g., the server heat pump operations apparatus 140 and/or the local heat pump operations apparatus 115) may be configured to generate a wind decoupled lifecycle impact determination interface component 1300. In some embodiments, the wind decoupled lifecycle impact determination interface component 1300 may comprise renderings of one or more determinations made by the heat pump operations apparatus when the heat pump operations apparatus is generating the wind decoupled lifecycle impact data. In some embodiments, such as illustrated in FIG. 13, the heat pump operations apparatus (e.g., the server heat pump operations apparatus 140 and/or the local heat pump operations apparatus 115) may be configured to cause rendering of the wind decoupled lifecycle impact determination interface component 1300 on the lifecycle impact interface 600.

In some embodiments, the one or more lifecycle impact evaluations may include a solar integrated lifecycle impact evaluation. In this regard, for example, the heat pump operations apparatus (e.g., the server heat pump operations apparatus 140 and/or the local heat pump operations apparatus 115) may be configured to perform a solar integrated lifecycle impact evaluation. In some embodiments, a solar integrated lifecycle impact evaluation may be performed for a solar integrated domain that includes a data center component, a heat pump component configured to provide heat to a district heating component, a solar power component configured to provide power to the data center component, one or more units (X) (e.g., the one or more units (X) being one or more homes to be heated), and/or the district heating component In some embodiments, the heat pump operations apparatus may be configured to generate solar integrated lifecycle impact data by performing a solar integrated lifecycle impact evaluation. In this regard, for example, the heat pump operations apparatus may be configured to generate solar integrated lifecycle impact data by performing one or more solar integrated lifecycle impact evaluations using a simulation tool (e.g., SimaPro 9.5.0), using a database (e.g., the eco-invent 3.8 database), and/or following an ISO 14040/14044 methodology.

In some embodiments, solar integrated lifecycle impact data may include one or more items of data representative and/or indicative of an amount of greenhouse gas (e.g., carbon dioxide) that is embodied in a data center component in the solar integrated domain (e.g., an amount of greenhouse gas that was generated in the construction of the data center component in the solar integrated domain before the data center component went into operation). Additionally, or alternatively, solar integrated lifecycle impact data may include one or more items of data representative and/or indicative of an amount of greenhouse gas (e.g., carbon dioxide) that is associated with operating the data center component in the solar integrated domain (e.g., operation of the data center component in the solar integrated domain after it has been constructed). Additionally, or alternatively, solar integrated lifecycle impact data may include one or more items of data representative and/or indicative of an amount of greenhouse gas (e.g., carbon dioxide) that is embodied in a heat pump component in the solar integrated domain (e.g., an amount of greenhouse gas that was generated in the construction of the heat pump component in the solar integrated domain before the heat pump component went into operation). Additionally, or alternatively, solar integrated lifecycle impact data may include one or more items of data representative and/or indicative of an amount of greenhouse gas (e.g., carbon dioxide) that is associated with operating the heat pump component in the solar integrated domain (e.g., operation of the heat pump component in the solar integrated domain after it has been constructed). Additionally, or alternatively, solar integrated lifecycle impact data may include one or more items of data representative and/or indicative of a number of units associated with the solar integrated domain (e.g., the one or more units (X)). For example, solar integrated lifecycle impact data may include one or more items of data representative and/or indicative of a number of homes that may be heated by the boiler component of the solar integrated domain.

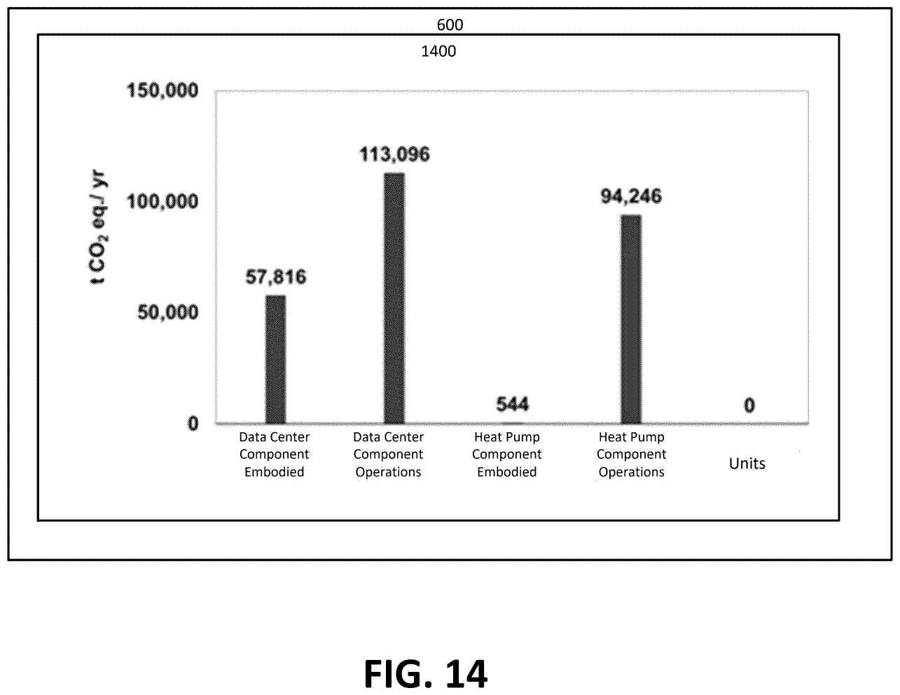

In some embodiments, the heat pump operations apparatus (e.g., the server heat pump operations apparatus 140 and/or the local heat pump operations apparatus 115) may be configured to generate a solar integrated lifecycle impact interface component 1400. In some embodiments, the solar integrated lifecycle impact interface component 1400 may comprise solar integrated lifecycle impact data. In some embodiments, such as illustrated in FIG. 14, the heat pump operations apparatus (e.g., the server heat pump operations apparatus 140 and/or the local heat pump operations apparatus 115) may be configured to cause rendering of the solar integrated lifecycle impact interface component 1400 on a lifecycle impact interface 600.

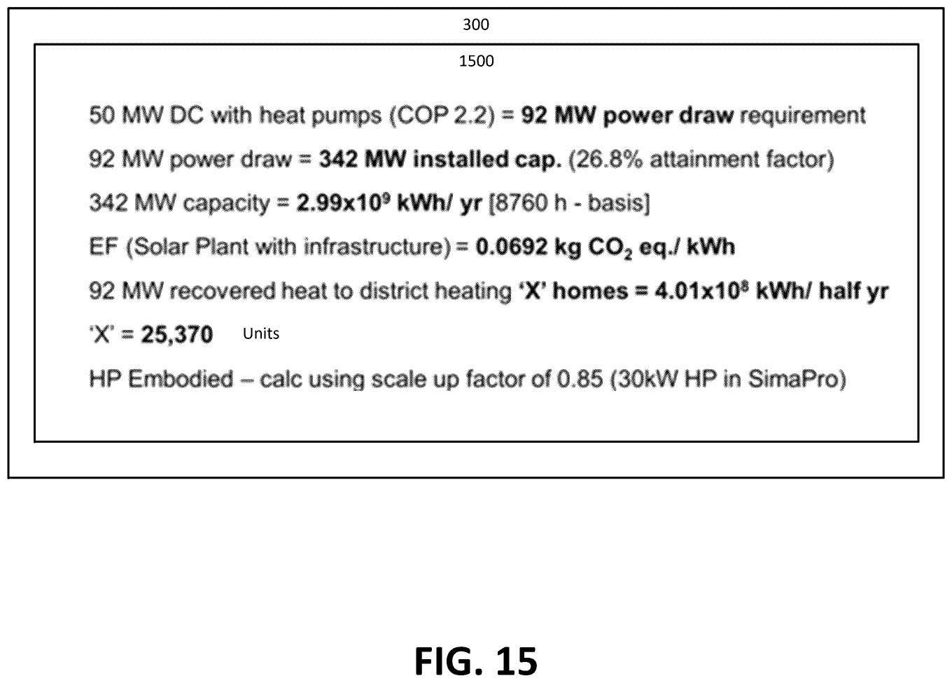

In some embodiments, the heat pump operations apparatus (e.g., the server heat pump operations apparatus 140 and/or the local heat pump operations apparatus 115) may be configured to generate a solar integrated lifecycle impact determination interface component 1500. In some embodiments, the solar integrated lifecycle impact determination interface component 1500 may comprise renderings of one or more determinations made by the heat pump operations apparatus when the heat pump operations apparatus is generating the solar integrated lifecycle impact data. In some embodiments, such as illustrated in FIG. 15, the heat pump operations apparatus (e.g., the server heat pump operations apparatus 140 and/or the local heat pump operations apparatus 115) may be configured to cause rendering of the solar integrated lifecycle impact determination interface component 1500 on the lifecycle impact interface 600.

In some embodiments, the one or more lifecycle impact evaluations may include a wind integrated lifecycle impact evaluation. In this regard, for example, the heat pump operations apparatus (e.g., the server heat pump operations apparatus 140 and/or the local heat pump operations apparatus 115) may be configured to perform a wind integrated lifecycle impact evaluation. In some embodiments, a wind integrated lifecycle impact evaluation may be performed for a wind integrated domain that includes a data center component, a heat pump component configured to provide heat to a district heating component, a wind power component configured to provide power to the data center component, one or more units (X) (e.g., the one or more units (X) being one or more homes to be heated), and/or the district heating component In some embodiments, the heat pump operations apparatus may be configured to generate wind integrated lifecycle impact data by performing a wind integrated lifecycle impact evaluation. In this regard, for example, the heat pump operations apparatus may be configured to generate wind integrated lifecycle impact data by performing one or more wind integrated lifecycle impact evaluations using a simulation tool (e.g., SimaPro 9.5.0), using a database (e.g., the eco-invent 3.8 database), and/or following an ISO 14040/14044 methodology.

In some embodiments, wind integrated lifecycle impact data may include one or more items of data representative and/or indicative of an amount of greenhouse gas (e.g., carbon dioxide) that is embodied in a data center component in the wind integrated domain (e.g., an amount of greenhouse gas that was generated in the construction of the data center component in the wind integrated domain before the data center component went into operation). Additionally, or alternatively, wind integrated lifecycle impact data may include one or more items of data representative and/or indicative of an amount of greenhouse gas (e.g., carbon dioxide) that is associated with operating the data center component in the wind integrated domain (e.g., operation of the data center component in the wind integrated domain after it has been constructed). Additionally, or alternatively, wind integrated lifecycle impact data may include one or more items of data representative and/or indicative of an amount of greenhouse gas (e.g., carbon dioxide) that is embodied in a heat pump component in the wind integrated domain (e.g., an amount of greenhouse gas that was generated in the construction of the heat pump component in the wind integrated domain before the heat pump component went into operation). Additionally, or alternatively, wind integrated lifecycle impact data may include one or more items of data representative and/or indicative of an amount of greenhouse gas (e.g., carbon dioxide) that is associated with operating the heat pump component in the wind integrated domain (e.g., operation of the heat pump component in the wind integrated domain after it has been constructed). Additionally, or alternatively, wind integrated lifecycle impact data may include one or more items of data representative and/or indicative of a number of units associated with the wind integrated domain (e.g., the one or more units (X)). For example, wind integrated lifecycle impact data may include one or more items of data representative and/or indicative of a number of homes that may be heated by the boiler component of the wind integrated domain.

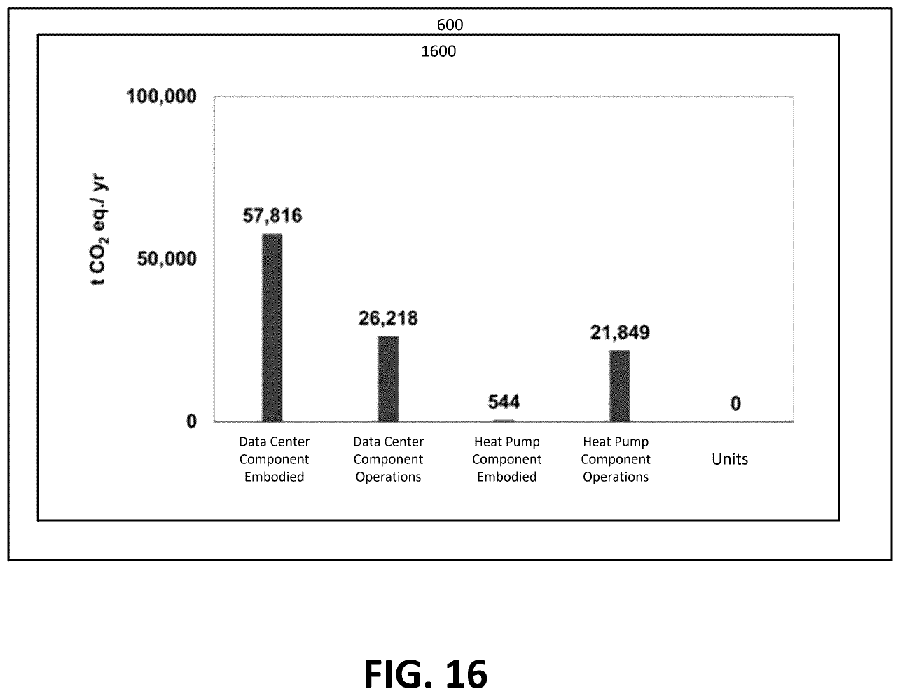

In some embodiments, the heat pump operations apparatus (e.g., the server heat pump operations apparatus 140 and/or the local heat pump operations apparatus 115) may be configured to generate a wind integrated lifecycle impact interface component 1600. In some embodiments, the wind integrated lifecycle impact interface component 1600 may comprise wind integrated lifecycle impact data. In some embodiments, such as illustrated in FIG. 16, the heat pump operations apparatus (e.g., the server heat pump operations apparatus 140 and/or the local heat pump operations apparatus 115) may be configured to cause rendering of the wind integrated lifecycle impact interface component 1600 on a lifecycle impact interface 600.

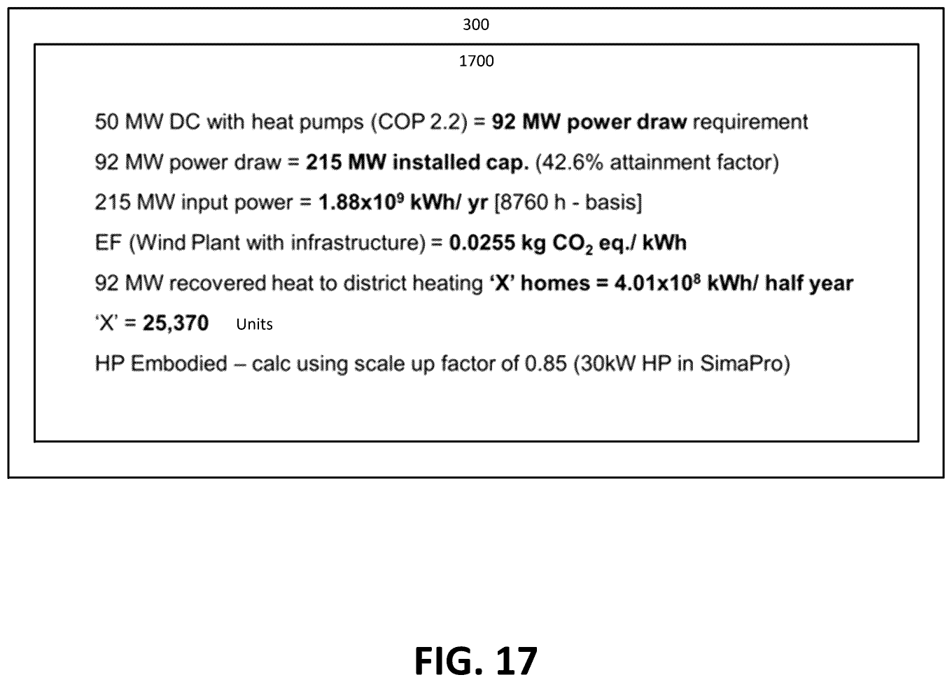

In some embodiments, the heat pump operations apparatus (e.g., the server heat pump operations apparatus 140 and/or the local heat pump operations apparatus 115) may be configured to generate a wind integrated lifecycle impact determination interface component 1700. In some embodiments, the wind integrated lifecycle impact determination interface component 1700 may comprise renderings of one or more determinations made by the heat pump operations apparatus when the heat pump operations apparatus is generating the wind integrated lifecycle impact data. In some embodiments, such as illustrated in FIG. 17, the heat pump operations apparatus (e.g., the server heat pump operations apparatus 140 and/or the local heat pump operations apparatus 115) may be configured to cause rendering of the wind integrated lifecycle impact determination interface component 1700 on the lifecycle impact interface 600.

### Example Methods

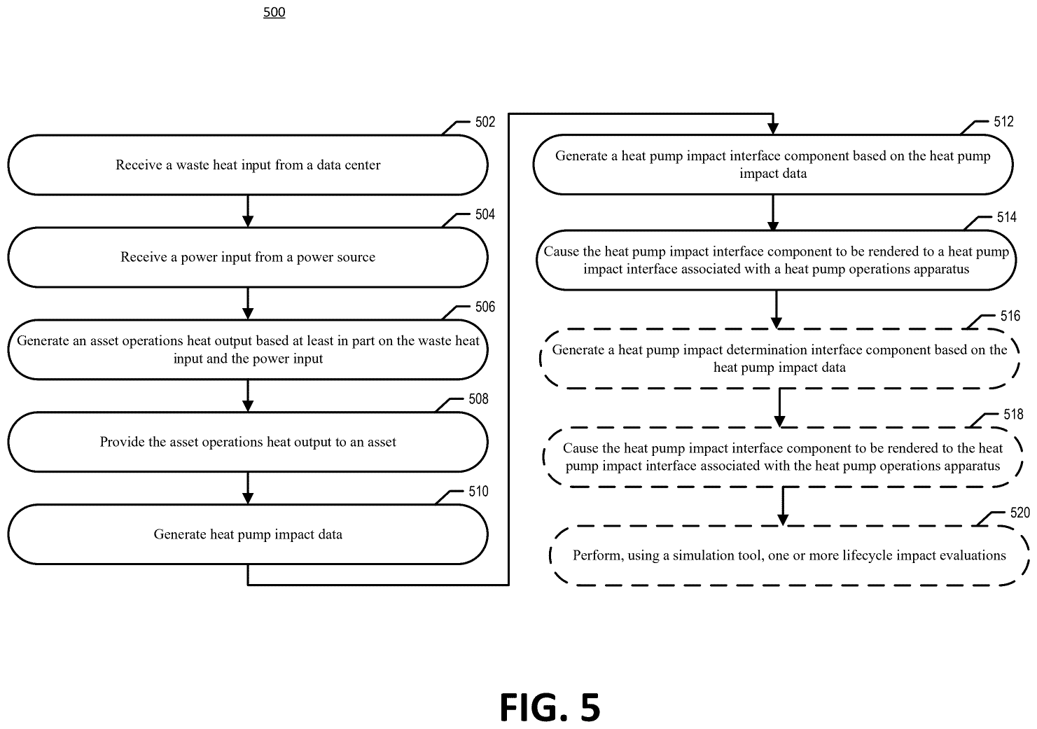

Referring now to FIG. 5, a flowchart providing an example method 500 is illustrated. In this regard, FIG. 5 illustrates operations that may be performed by the heat pump operations apparatus (e.g., the server heat pump operations apparatus 140 and/or the local heat pump operations apparatus 115), the heat pump 110, the power source 160, the data center 150, the asset 102, and/or the one or more databases 170. In some embodiments, the example method 500 defines a process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 500.

As shown in block 502, the method 500 may include receiving a waste heat input from a data center. As described above, in some embodiments, the waste heat input may be representative of waste and/or excessive heat that is generated by the data center when the data center is processing, storing, generating, and/or transporting data. In some embodiments, the waste heat input may be associated with a first temperature. In some embodiments, the first temperature may be between 20° C. and 40° C. For example, the first temperature may be approximately 30° C.

As shown in block 504, the method 500 may include receiving a power input from a power source. As described above, in some embodiments, the power input may be received from the power source. In this regard, for example, power input may be based on solar power (e.g., the power source is a solar plant). Additionally, or alternatively, the power input may be based on wind power (e.g., the power source is a wind plant). Additionally, or alternatively, the power input may be based on natural gas (e.g., the power source a natural gas plant). Additionally, or alternatively, the power input may be based on nuclear power (e.g., the power source is a nuclear power plant). Additionally, or alternatively, the power input may be based on hydroelectric power (e.g., the power source is a hydroelectric power plant). Additionally, or alternatively, the power input may be based on a mix of sources capable of generating and/or providing power (e.g., the power source is an electric grid). In some embodiments, the power input may be between 40 megawatts (MW) and 60 MW. For example, the power input may be approximately 52 MW.

As shown in block 506, the method 500 may include generating an asset operations heat output based at least in part on the waste heat input and the power input. As described above, in some embodiments, the asset operations heat output may be generated based at least in part on the waste heat input (e.g., the waste heat input received from the data center). Additionally, or alternatively, the asset operations heat output may be generated based at least in part on the power input (e.g., the power input received from the power source). In this regard, for example, the heat pump may be configured to use heat from a source (e.g., the waste heat input) to heat up a refrigerant associated with the heat pump (e.g., R1234ze (E)) to produce a saturated vapor. In some embodiments, the heat pump may be configured to compress the saturated vapor to increase the temperature of the refrigerant to generate a heated refrigerant. In some embodiments, for example, the heat pump may be configured to use the power input to compress the saturated vapor. In some embodiments, the heat pump is configured to condense the heated refrigerant to produce an output that is a higher temperature than the input into the heat pump (e.g., the asset operations heat output). In some embodiments, for example, the heat pump may be configured to use the power input to condense the heated refrigerant.

In some embodiments, the asset operations heat output may be associated with a second temperature. In some embodiments, the second temperature may be between 85° C. and 105° C. For example, the second temperature may be approximately 95° C. In this regard, for example, the asset operations heat output may be associated with a second temperature that is less than 160° C. Additionally, or alternatively, for example, the asset operations heat output may be associated with a second temperature that is less than 140° C. In some embodiments, the second temperature may be greater than the first temperature. In this regard, for example, the heat pump may be configured to intake waste heat and increase the temperature of the waste heat. In some embodiments, the second temperature may be of a sufficient temperature such that it may be used for the operation of the asset (e.g., for the operation of a direct air capture system). That is, for example, by being between 85° C. and 105° C. the second temperature may be of a sufficient temperature such that it may be used for operation of the asset.

As shown in block 508, the method 500 may include providing the asset operations heat output to an asset. As described above, in some embodiments, the heat pump may be configured to provide the asset operations heat output to a distributed heating system. Additionally, or alternatively, the heat pump may be configured to provide the asset operations heat output to a direct air capture system.

As shown in block 510, the method 500 may include generating heat pump impact data. As described above, in some embodiments, the heat pump operations apparatus (e.g., the server heat pump operations apparatus and/or the local heat pump operations apparatus) may be configured to generate heat pump impact data based at least in part on the waste heat input, the power input, and/or the asset operations heat output.

As shown in block 512, the method 500 may include generating a heat pump impact interface component based on the heat pump impact data. As described above, in some embodiments, the heat pump impact interface component may comprise heat pump impact data. In some embodiments, for example, the heat pump impact interface component may be configured to display heat pump impact data that is indicative of an amount of greenhouse gas (e.g., carbon dioxide) that is embodied in the data center. As another example, the heat pump impact interface component may be configured to display heat pump impact data that is indicative of an amount of greenhouse gas (e.g., carbon dioxide) that is associated with operating the data center. As another example, the heat pump impact interface component may be configured to display heat pump impact data that is indicative of an amount of greenhouse gas (e.g., carbon dioxide) that is embodied in the heat pump and an amount of greenhouse gas (e.g., carbon dioxide) that is embodied in the asset.

As another example, the heat pump impact interface component may be configured to display heat pump impact data that is indicative of an amount of greenhouse gas (e.g., carbon dioxide) that is associated with operating the heat pump and an amount of greenhouse gas (e.g., carbon dioxide) that is associated with operating the asset. As another example, the heat pump impact interface component may be configured to display heat pump impact data that is indicative of an amount of greenhouse gas (e.g., carbon dioxide) that is associated with adsorbent associated with the asset. As another example, the heat pump impact interface component may be configured to display heat pump impact data that is indicative of amount of greenhouse gas (e.g., carbon dioxide) that is captured using at least the heat pump and/or the asset.

As shown in block 514, the method 500 may include causing the heat pump impact interface component to be rendered to a heat pump impact interface associated with a heat pump operations apparatus.

As shown in optional block 516, the method 500 may optionally include generating a heat pump impact determination interface component based on the heat pump impact data. As described above, in some embodiments, the heat pump impact determination interface component may comprise renderings of one or more determinations made by the heat pump operations apparatus when the heat pump operations apparatus is generating the heat pump impact data. In this regard, for example, the heat pump impact determination interface component may be generated based on heat pump impact data.

As shown in optional block 518, the method 500 may optionally include causing the heat pump impact interface component to be rendered to the heat pump impact interface associated with the heat pump operations apparatus. As described above, in some embodiments, the heat pump impact interface may be associated with the heat pump operations apparatus (e.g., the server heat pump operations apparatus and/or the local heat pump operations apparatus). For example, the heat pump impact interface may be an interface displayed by the heat pump operations apparatus (e.g., on the heat pump operations apparatus). As another example, the heat pump impact interface may be displayed on an external computing device that has received heat pump impact data from the heat pump operations apparatus, the heat pump impact interface component from the heat pump operations apparatus, and/or the heat pump impact determination interface component from the heat pump operations apparatus.

As shown in optional block 520, the method 500 may optionally include performing, using a simulation tool, one or more lifecycle impact evaluations. As described above, in some embodiments, a lifecycle impact evaluation includes a lifecycle assessment (LCA). In this regard, for example, a lifecycle impact evaluation may include an evaluation of an environmental impact associated with a domain over a lifetime of one or more components of the domain. For example, a lifecycle impact evaluation may include an evaluation of an environmental impact associated with a domain that includes one or more power generation components and/or one or more heated components. In some embodiments, the heat pump operations apparatus (e.g., the server heat pump operations apparatus and/or the local heat pump operations apparatus) may be configured to perform one or more lifecycle impact evaluations using a simulation tool (e.g., SimaPro 9.5.0), using a database (e.g., the eco-invent 3.8 database), and/or following a methodology (e.g., an ISO 14040/14044 methodology. In this regard, for example, the heat pump operations apparatus may be configured to establish global warming potential in metric tons equivalent of carbon dioxide per year (t CO₂ₑ/y) for various different power generation and/or heat generation techniques.

### CONCLUSION

Operations and/or functions of the present disclosure have been described herein, such as in flowcharts. As will be appreciated, computer program instructions may be loaded onto a computer or other programmable apparatus (e.g., hardware) to produce a machine, such that the resulting computer or other programmable apparatus implements the operations and/or functions described in the flowchart blocks herein. These computer program instructions may also be stored in a computer-readable memory that may direct a computer, processor, or other programmable apparatus to operate and/or function in a particular manner, such that the instructions stored in the computer-readable memory produce an article of manufacture, the execution of which implements the operations and/or functions described in the flowchart blocks. The computer program instructions may also be loaded onto a computer, processor, or other programmable apparatus to cause a series of operations to be performed on the computer, processor, or other programmable apparatus to produce a process such that the instructions executed on the computer, processor, or other programmable apparatus provide operations for implementing the functions and/or operations specified in the flowchart blocks. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

Similarly, while operations are illustrated in the drawings in a particular order, this should not be understood as requiring that such operations be performed in the particular order shown or in sequential order, or that all illustrated operations be performed, to achieve desirable results. In certain circumstances, operations in alternative ordering may be advantageous. In some cases, the actions recited in the claims may be performed in a different order and still achieve desirable results.

1. A system comprising:
a heat pump, wherein the heat pump is configured to:
receive a waste heat input from a data center, wherein the waste heat input is associated with a first temperature;
receive a power input from a power source;
generate an asset operations heat output based on the waste heat input and the power input, wherein the asset operations heat output is associated with a second temperature, wherein the second temperature is greater than the first temperature; and
provide the asset operations heat output to an asset; and
a heat pump operations apparatus comprising at least one processor and at least one non-transitory memory including computer-coded instructions thereon, the computer-coded instructions, with the at least one processor, cause the heat pump operations apparatus to:
generate heat pump impact data;
generate a heat pump impact interface component based on the heat pump impact data, wherein the heat pump impact interface component comprises at least a portion of the heat pump impact data; and
cause the heat pump impact interface component to be rendered to a heat pump impact interface associated with the heat pump operations apparatus.

2. The system of claim 1, wherein the computer-coded instructions, with the at least one processor, further cause the heat pump operations apparatus to:
generate a heat pump impact determination interface component based on the heat pump impact data; and
cause the heat pump impact interface component to be rendered to the heat pump impact interface associated with the heat pump operations apparatus.

3. The system of claim 1, wherein the computer-coded instructions, with the at least one processor, further cause the heat pump operations apparatus to:
perform, using a simulation tool, one or more lifecycle impact evaluations.

4. The system of claim 3, wherein the one or more lifecycle impact evaluations comprise one or more of a conventional decoupled lifecycle impact evaluation, a conventional integrated lifecycle impact evaluation, a solar decoupled lifecycle impact evaluation, a wind decoupled lifecycle impact evaluation, a solar integrated lifecycle impact evaluation, or a wind integrated lifecycle impact evaluation.

5. The system of claim 1, wherein the asset is a direct air capture system or a district heating system.

6. The system of claim 1, wherein the power source comprises solar power or wind power.

7. The system of claim 1, wherein the heat pump operations apparatus is a server heat pump operations apparatus.

8. The system of claim 7, wherein the heat pump is located at a first location and the server heat pump operations apparatus is located at a second location.

9. The system of claim 1, wherein the heat pump operations apparatus is a local heat pump operations apparatus.

10. The system of claim 9, wherein the heat pump is located at a first location and the local heat pump operations apparatus is located at the first location.

11. The system of claim 1, wherein the heat pump impact data is representative of at least greenhouse gas data.

12. A method comprising:
receiving a waste heat input from a data center, wherein the waste heat input is associated with a first temperature;
receiving a power input from a power source;
generating an asset operations heat output based on the waste heat input and the power input, wherein the asset operations heat output is associated with a second temperature, wherein the second temperature is greater than the first temperature;
providing the asset operations heat output to an asset;
generating heat pump impact data;
generating a heat pump impact interface component based on the heat pump impact data, wherein the heat pump impact interface component comprises at least a portion of the heat pump impact data; and
causing the heat pump impact interface component to be rendered to a heat pump impact interface associated with a heat pump operations apparatus.

13. The method of claim 12, further comprising:
generating a heat pump impact determination interface component based on the heat pump impact data; and
causing the heat pump impact interface component to be rendered to the heat pump impact interface associated with the heat pump operations apparatus.

14. The method of claim 12, further comprising:
performing, using a simulation tool, one or more lifecycle impact evaluations.

15. The method of claim 14, wherein the one or more lifecycle impact evaluations comprise one or more of a conventional decoupled lifecycle impact evaluation, a conventional integrated lifecycle impact evaluation, a solar decoupled lifecycle impact evaluation, a wind decoupled lifecycle impact evaluation, a solar integrated lifecycle impact evaluation, or a wind integrated lifecycle impact evaluation.

16. The method of claim 12, wherein the asset is a direct air capture system or a district heating system.

17. The method of claim 12, wherein the power source comprises solar power or wind power.

18. The method of claim 12, wherein the heat pump impact data is generated by a server heat pump operations apparatus.

19. The method of claim 12, wherein the heat pump impact data is representative of at least greenhouse gas data.

20. A non-transitory computer-readable medium storing software comprising instructions executable by one or more apparatuses which, upon such execution, cause the one or more apparatuses to:
receive a waste heat input from a data center, wherein the waste heat input is associated with a first temperature;
receive a power input from a power source;
generate an asset operations heat output based on the waste heat input and the power input, wherein the asset operations heat output is associated with a second temperature, wherein the second temperature is greater than the first temperature;
provide the asset operations heat output to an asset;
generate heat pump impact data;
generate a heat pump impact interface component based on the heat pump impact data, wherein the heat pump impact interface component comprises at least a portion of the heat pump impact data; and
cause the heat pump impact interface component to be rendered to a heat pump impact interface associated with a heat pump operations apparatus.
